(19) United States
(12) Patent Application Publication
(10) Pub. No.: US 2026/0223350 A1
(43) Pub. Date: Jul. 30, 2026

(54) SEMICONDUCTOR MEMORY DEVICE

(71) Applicant: Samsung Electronics Co., Ltd., Suwon-si (KR)

(72) Inventors: Kyung Hwan LEE, Suwon-si (KR); Won Sok LEE, Suwon-si (KR); Jung Pyo HONG, Suwon-si (KR)

(21) Appl. No.: 19/283,693

(22) Filed: Jul. 29, 2025

(30) Foreign Application Priority Data
Jan. 24, 2025 (KR) 10-2025-0011298

(51) Int. Cl. H10B 12/00

(52) U.S. Cl. CPC H10B 12/00

(57) ABSTRACT

A semiconductor memory device includes a first conductive line, a first bitline spaced apart from the first conductive line in a first direction, a second bitline spaced apart from the first conductive line in the first direction, a first wordline disposed between the first conductive line and each of the first bitline and the second bitline, a first channel pattern including a horizontal portion and disposed between the first wordline and the first conductive line and a first vertical portion, the horizontal portion of the first channel pattern being connected to the first conductive line, and the first vertical portion of the first channel pattern being connected to the first bitline, and a second channel pattern disposed between the first channel pattern and the first wordline and connected to the second bitline.

### CROSS-REFERENCE TO RELATED APPLICATION

This application claims priority from Korean Patent Application No. 10-2025-0011298 filed on Jan. 24, 2025 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor memory device and a method of fabricating the same, and more specifically, to a semiconductor memory device including a vertical channel transistor (VCT) and a method for fabricating the semiconductor memory device.

### 2. Description of the Related Art

To meet consumer demands for superior performance at a lower cost, increasing the integration density of semiconductor memory devices is desirable. For semiconductor memory devices, integration density is a crucial factor in determining product cost, making higher integration density particularly desirable.

For two-dimensional (2D) or planar semiconductor memory devices, integration density is primarily determined by the area occupied by a unit memory cell, which is significantly influenced by the level of fine pattern formation technology. However, achieving finer patterning in 2D semiconductor memory devices necessitates extremely costly equipment. As a result, while integration density has increased, it remains constrained. Accordingly, semiconductor memory devices incorporating vertical channel transistors (VCTs), in which the channels extend vertically relative to an upper surface of a substrate, have been proposed.

### SUMMARY

An objective of the present disclosure is to provide a semiconductor memory device with improved integration density and electrical characteristics.

Another objective of the present disclosure is to provide a method for fabricating a semiconductor memory device with improved integration density and electrical characteristics.

The objectives of the present disclosure are not limited to those mentioned above, and other objectives not explicitly stated will be clearly understood by those skilled in the art based on the following description.

According to an aspect of the present disclosure, a semiconductor memory device includes a first conductive line on a substrate, a first bitline spaced apart from the first conductive line in a first direction and extending in a second direction, a second bitline spaced apart from the first conductive line in the first direction, extending in the second direction, and spaced apart from the first bitline in a third direction, a first wordline disposed between the first conductive line and each of the first bitline and the second bitline and extending in the third direction, a first channel pattern including a horizontal portion extending in the second direction and disposed between the first wordline and the first conductive line and a first vertical portion extending in the first direction, wherein the horizontal portion of the first channel pattern is connected to the first conductive line, and wherein the first vertical portion of the first channel pattern is connected to the first bitline, and a second channel pattern disposed between the first channel pattern and the first wordline and connected to the second bitline.

According to an aspect of the present disclosure, a semiconductor memory device includes a conductive line on a substrate, a first bitline spaced apart from the conductive line in a first direction and extending in a second direction, a second bitline spaced apart from the conductive line in the first direction, extending in the second direction, and spaced apart from the first bitline in a third direction, a first wordline disposed between the conductive line and each of the first bitline and the second bitline and extending in the third direction, a first channel pattern disposed between the first wordline and the conductive line and connected to the first bitline and the conductive line, and a second channel pattern disposed between the first channel pattern and the first wordline and connected to the second bitline. The first wordline includes a first sidewall and a second sidewall that are opposite to each other in the second direction. The second channel pattern includes a first vertical portion extending along the first sidewall of the first wordline, a second vertical portion extending along the second sidewall of the first wordline, and a horizontal portion including a first end connected to the first vertical portion and a second end connected to the second vertical portion.

According to an aspect of the present disclosure, a semiconductor memory device includes a conductive line disposed on a substrate and extending in a first direction, a first bitline spaced apart from the conductive line in a second direction and extending in the first direction, a second bitline spaced apart from the conductive line in the second direction, extending in the first direction, and spaced apart from the first bitline in a third direction, a first channel pattern including a horizontal portion extending in the first direction, a first vertical portion extending in the second direction, and a second vertical portion extending in the second direction, wherein the first vertical portion of the first channel pattern and the second vertical portion of the first channel pattern are directly connected to opposite ends of the horizontal portion of the first channel pattern, respectively, wherein the horizontal portion of the first channel pattern is connected to the conductive line, and wherein the first vertical portion of the first channel pattern and the second vertical portion of the first channel pattern are connected to the first bitline, a first wordline disposed between the first vertical portion of the first channel pattern and the second vertical portion of the first channel pattern, a second wordline disposed between the first wordline and the second vertical portion of the first channel pattern, and a second channel pattern disposed between the first channel pattern and each of the first wordline and the second wordline and connected to the second bitline.

According to an aspect of the present disclosure, there is provided a method of fabricating a semiconductor memory device, comprising forming a conductive line, forming a first mold pattern on the conductive line, the first mold pattern including a first channel trench extending in a first direction, forming a pre-lower channel pattern extending along sidewalls and a bottom surface of the first channel trench and extending in the first direction, forming a channel cutting pattern inside the first mold pattern to separate the pre-lower channel pattern, thereby forming a second mold pattern defining a second channel trench, wherein a lower channel pattern separated by the channel cutting pattern is formed within the second channel trench, forming a first pre-upper channel pattern on the lower channel pattern, wherein the first pre-upper channel pattern is formed along sidewalls and a bottom surface of the second channel trench, removing a portion of the second mold pattern and a portion of the first pre-upper channel pattern to form a wordline trench extending in the first direction, wherein during the formation of the wordline trench, a second pre-upper channel pattern is formed, forming a first wordline mold spacer and a second wordline mold spacer extending in the first direction within the wordline trench, wherein the first wordline mold spacer and the second wordline mold spacer are spaced apart in a second direction perpendicular to the first direction, forming a wordline separation pattern extending in the first direction between the first wordline mold spacer and the second wordline mold spacer, removing the first wordline mold spacer and the second wordline mold spacer to form a first mold spacer trench and a second mold spacer trench, forming a first wordline and a second wordline inside the first mold spacer trench and the second mold spacer trench, removing a portion of the wordline separation pattern to form a channel hole between the first wordline and the second wordline, wherein the channel hole exposes a portion of the second pre-upper channel pattern, forming a third pre-upper channel pattern inside the channel hole in contact with the second pre-upper channel pattern to form an upper channel pattern on the lower channel pattern, and forming a first bitline connected to the lower channel pattern and a second bitline connected to the upper channel pattern on the lower channel pattern and the upper channel pattern.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing illustrative embodiments thereof in detail with reference to the attached drawings, in which:

FIG. 1 is a circuit diagram of a semiconductor memory device according to some embodiments.

FIGS. 2 and 3 are layout diagrams illustrating a semiconductor memory device according to some embodiments.

FIGS. 4, 5, 6, 7, and 8 are cross-sectional views taken along lines A-A, B-B, C-C, D-D, and E-E, respectively, of FIG. 3.

FIG. 9 is an enlarged cross-sectional view of portion P in FIG. 4.

FIG. 10 is a diagram illustrating the planar shape of an upper connection channel pattern in FIGS. 2 and 3.

FIG. 11 is a diagram illustrating a semiconductor memory device according to some embodiments.

FIG. 12 is a diagram illustrating a semiconductor memory device according to some embodiments.

FIGS. 13 and 14 are diagrams illustrating a semiconductor memory device according to some embodiments.

FIGS. 15 and 16 are diagrams illustrating a semiconductor memory device according to some embodiments.

FIGS. 17 and 18 are diagrams illustrating a semiconductor memory device according to some embodiments.

FIGS. 19, 20, 21, 22, and 23 are diagrams illustrating a semiconductor memory device according to some embodiments.

FIG. 24 is a diagram illustrating a semiconductor memory device according to some embodiments.

FIG. 25 is a diagram illustrating a semiconductor memory device according to some embodiments.

FIGS. 26, 27, 28, 29, 30, 31, 32, 33, 34, 35, 36, 37, 38, 39, 40, 41, 42, 43, 44, 45, 46, 47, 48, 49, 50, 51, and 52, and 53 are diagrams illustrating a method of fabricating a semiconductor memory device according to some embodiments.

### DETAILED DESCRIPTION

It will be understood that, although the terms “first”, “second”, “third”, and so on may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section described below could be termed a second element, component, region, layer, or section without departing from the sprit and scope of the present disclosure.

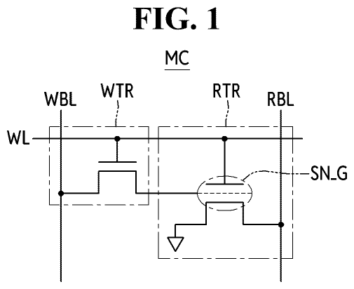

FIG. 1 is a circuit diagram of a semiconductor memory device according to some embodiments.

Referring to FIG. 1, a memory cell MC may include a write transistor WTR and a read transistor RTR connected to the write transistor WTR. Although not illustrated, the semiconductor memory device according to some embodiments may include a plurality of memory cells MC arranged in a two-dimensional (2D) or three-dimensional (3D) manner.

The write transistor WTR may include a wordline WL connected to a gate terminal of the write transistor WTR and a write bitline WBL connected to a source terminal of the write transistor WTR. The read transistor RTR may include the wordline WL connected to a gate terminal of the read transistor RTR and a read bitline RBL connected to a drain terminal of the read transistor RTR. The wordline WL may be connected to the gate terminals of the read transistor RTR and the write transistor WTR. The wordline WL may be shared by the write transistor WTR and the read transistor RTR. A source terminal of the read transistor RTR may be connected to a ground voltage, but is not limited thereto. Contrary to what is illustrated, the read transistor RTR may include a read wordline connected to the source terminal of the read transistor RTR.

A drain terminal of the write transistor WTR may be connected to the gate terminal of the read transistor RTR. The drain terminal of the write transistor WTR may be referred to as a storage node gate SN_G. For example, the storage node gate SN_G may function as the gate of the read transistor RTR during a read operation of the read transistor RTR. The storage node gate SN_G may serve to store charge.

In one example, a program operation of the memory cell MC may be performed as follows. A voltage may be applied to the wordline WL and the write bitline WBL, turning on the write transistor WTR. As the write transistor WTR is turned on, an electrical signal (or charge) may be transferred (or charged) to the storage node gate SN_G. Accordingly, the electrical signal from the write bitline WBL may be stored in the storage node gate SN_G, resulting in a change in the threshold voltage of the read transistor RTR.

When a voltage is applied to the wordline WL, the voltage may be applied to the gate terminal of the read transistor RTR. During the program operation of the memory cell MC, it is necessary to prevent an electrical signal from moving into the channel region of the read transistor RTR. During the program operation of the memory cell MC, a ground voltage may be applied to the read bitline RBL connected to the drain terminal of the read transistor RTR, preventing a potential difference between the drain terminal and the source terminal of the read transistor RTR.

In one example, a read operation of the memory cell MC may be performed as follows. The write transistor WTR may be turned off, and a voltage may be applied to the read bitline RBL. Through the current flowing through the read transistor RTR, the electrical signal stored in the storage node gate SN_G may be read through the read bitline RBL.

A semiconductor memory device including the memory cell MC may also be referred to as a two-transistor zero-capacitor (2T-0C) memory device. The semiconductor memory device according to some embodiments may not include a separate capacitor for storing electric charges.

Accordingly, since the area required for forming a capacitor may be reduced, high integration may be achieved for the semiconductor memory device according to some embodiments, and the manufacturing cost of the semiconductor memory device according to some embodiments may be reduced. In addition, by omitting the formation of capacitors, a memory cell array including a plurality of memory cells MC may be vertically stacked. This may enable high integration for the semiconductor memory device according to some embodiments.

Furthermore, as a single wordline WL is shared by the write transistor WTR and the read transistor RTR, the number of conductive lines formed in the memory cell MC may be reduced. As a result, the area in which the memory cell array is formed may be reduced. Therefore, high integration for the semiconductor memory device according to some embodiments may be achieved.

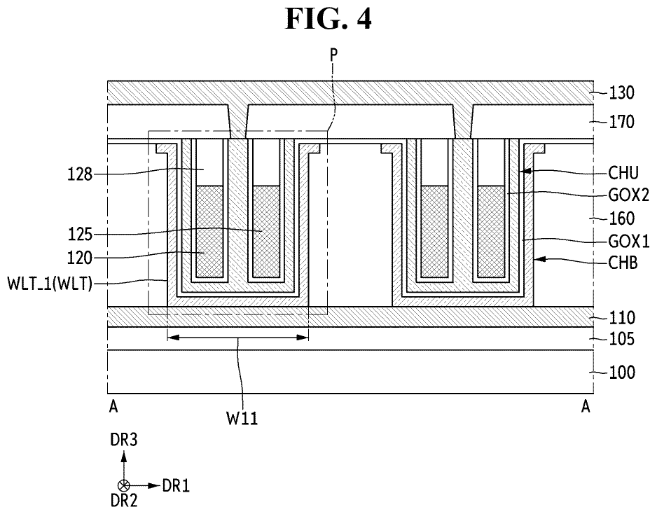

A semiconductor memory device including a 2T-0C memory device according to some embodiments may include a vertical channel transistor (VCT). The VCT may refer to a structure in which the channel of the transistor extends in a direction perpendicular to the upper surface of a substrate 100 (in a third direction DR3 (i.e., a vertical direction) in FIG. 4).

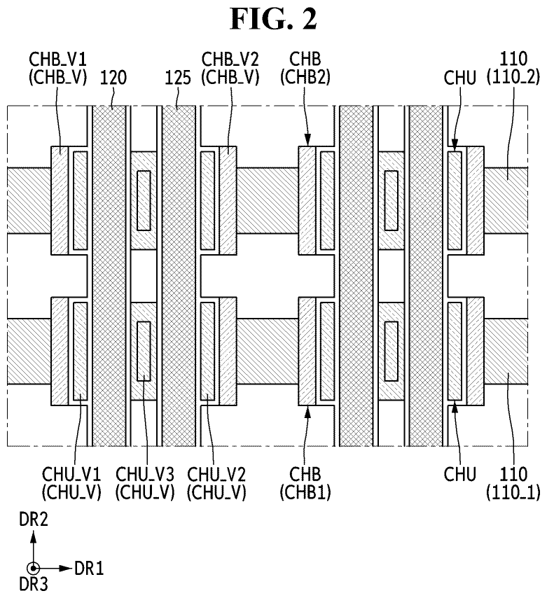

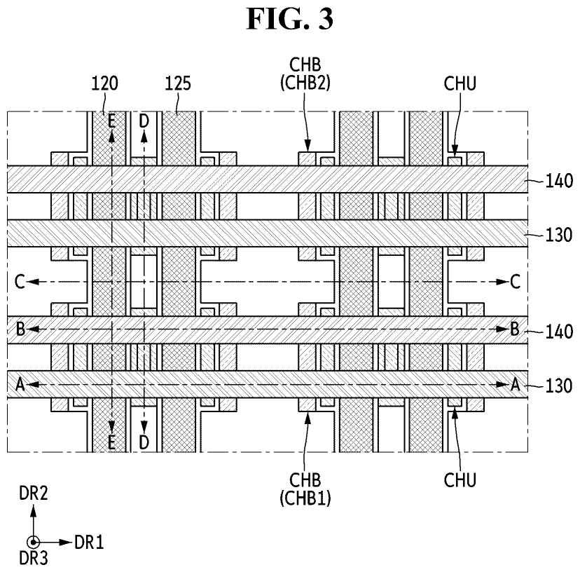

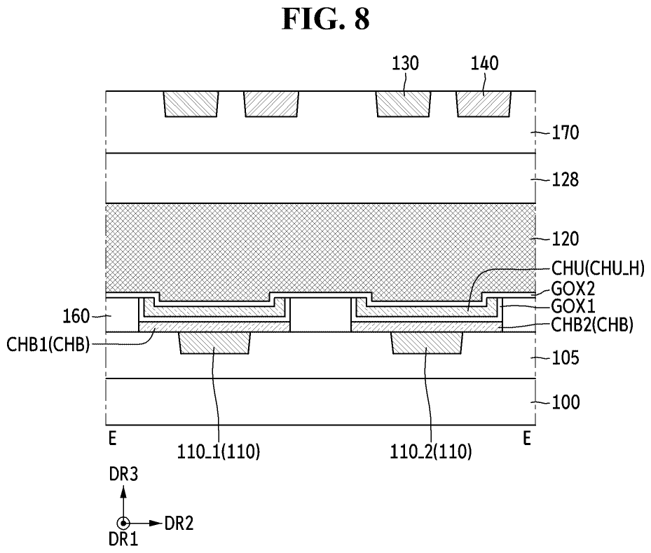

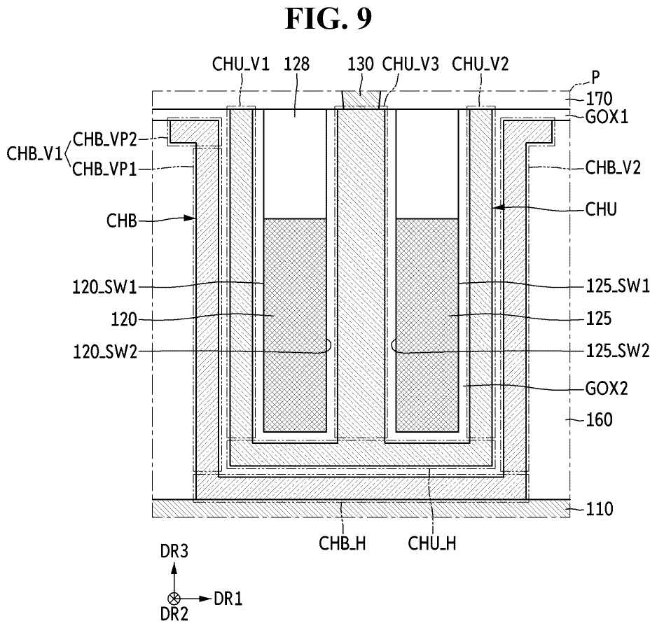

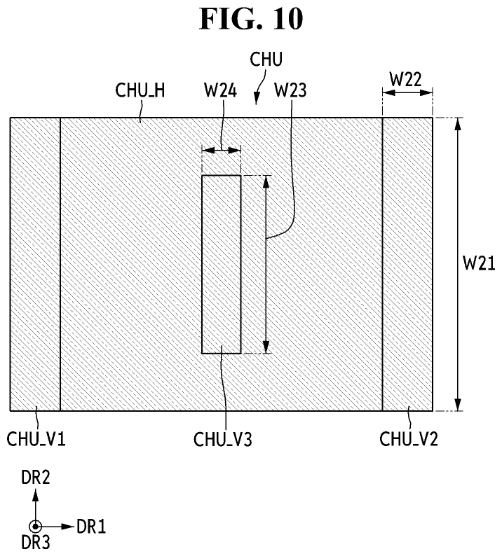

FIGS. 2 and 3 are layout diagrams illustrating a semiconductor memory device according to some embodiments. FIGS. 4, 5, 6, 7, and 8 are cross-sectional views taken along lines A-A, B-B, C-C, D-D, and E-E, respectively, of FIG. 3. FIG. 9 is an enlarged cross-sectional view of portion P in FIG. 4. FIG. 10 is a diagram illustrating the planar shape of an upper connection channel pattern in FIGS. 2 and 3.

Specifically, FIG. 2 illustrates the structure of the semiconductor memory device according to some embodiments, except for first bitlines 130 and second bitlines 140, and FIG. 3 illustrates the structure of the semiconductor memory device according to some embodiments, except for conductive lines 110.

Referring to FIGS. 1 through 10, the semiconductor memory device according to some embodiments may include conductive lines 110, lower connection channel patterns CHB (i.e., a first channel pattern), upper connection channel patterns CHU (i.e., a second channel pattern), first wordlines 120, second wordlines 125, first bitlines 130, and second bitlines 140.

In one example, the substrate 100 may be a silicon substrate or may include other materials, such as silicon-germanium, indium antimonide, a lead telluride compound, indium arsenide, indium phosphide, gallium arsenide, and gallium antimonide. In another example, the substrate 100 may include a ceramic substrate, a quartz substrate, or a glass substrate. In yet another example, the substrate 100 may include a flexible plastic material such as polyimide, polyethylene terephthalate (PET), polyethylene naphthalate (PEN), poly methyl methacrylate (PMMA), polycarbonate (PC), polyethersulfone (PES), and polyester.

A lower insulating film 105 may be disposed on the substrate 100. The lower insulating film 105 may include an insulating material. Contrary to what is illustrated, the lower insulating film 105 may not be disposed on the substrate 100. For example, the lower insulating film 105 may be omitted.

The conductive lines 110 may be disposed on the substrate 100. The conductive lines 110 may be disposed on the lower insulating film 105.

The conductive lines 110 may each extend in a first direction DR1 (i.e., a first horizontal direction). The conductive lines 110 may be adjacent to each other in a second direction DR2 (i.e., a second horizontal direction).

The conductive lines 110 may each include a first surface and a second surface that are opposite to each other in a third direction DR3. The second surfaces of the conductive lines 110 may face (i.e., may be adjacent to) the substrate 100.

Here, the first and second directions DR1 and DR2 may be perpendicular to the third direction DR3. The first direction DR1 may intersect the second direction DR2. For example, the third direction DR3 may be a thickness direction of the substrate 100. The first and second directions DR1 and DR2 may be parallel to the upper surface of the substrate 100.

In one example, the conductive lines 110 may be connected to a ground voltage. The conductive lines 110 may be connected to the source terminal of the read transistor RTR.

In the semiconductor memory device according to some embodiments, the conductive lines 110 may include a first conductive line 110_1 and a second conductive line 110_2. The first and second conductive lines 110_1 and 110_2 may each extend in the first direction DR1. The first and second conductive lines 110_1 and 110_2 may be spaced apart in the second direction DR2. By connecting adjacent lower connection channel patterns CHB in the second direction DR2 to different conductive lines 110, the sensing margin of a memory cell array may be improved.

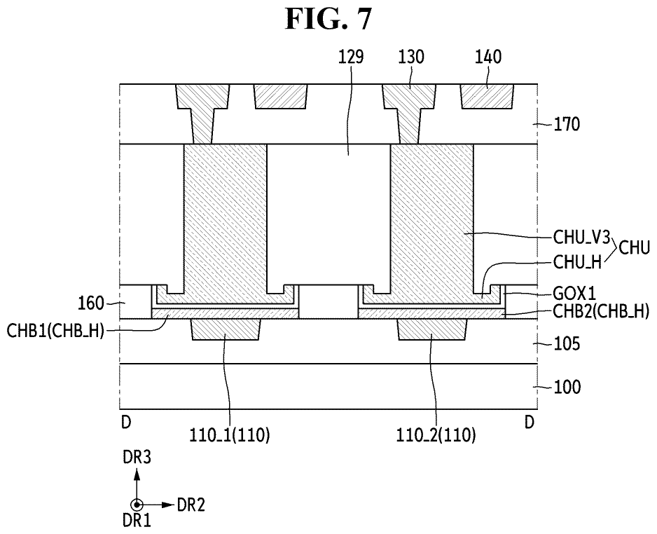

As shown in FIG. 7, the width of the conductive lines 110 in the second direction DR2 increases in the third direction DR3 from the substrate 100 toward the horizontal portion CHB_H of the lower connection channel pattern CHB, but is not limited thereto.

The conductive lines 110 may include a conductive material. The conductive lines 110 may include, for example, at least one of a doped semiconductor material, a conductive metal nitride, a conductive metal silicon nitride, a metal carbonitride, a conductive metal silicide, a conductive metal oxide, a 2D material, and a metal. The conductive lines 110 are illustrated as single films, but are not limited thereto.

In the semiconductor memory device according to some embodiments, the 2D material may be a metallic material and/or a semiconductor material. The 2D material may include a 2D allotrope or a 2D compound. For example, the 2D material may include graphene, molybdenum disulfide (MoS₂), molybdenum diselenide (MoSe₂), tungsten diselenide (WSe₂), tungsten disulfide (WS₂), copper disulfide (CuS₂), copper diselenide (CuSe₂), or a combination thereof, but is not limited thereto. For example, these 2D materials are listed as examples, and the 2D material that can be included in the semiconductor memory device according to some embodiments is not limited thereto.

A mold insulating pattern 160 may be disposed on the conductive line 110. The mold insulating pattern 160 may be disposed on the first surfaces of the conductive lines 110. Contrary to what is illustrated, an etch stop film may be disposed between the mold insulating pattern 160 and the conductive lines 110.

The mold insulating pattern 160 may include an insulating material. The mold insulating pattern 160 is illustrated as a single film, but is not limited thereto. If an etch stop film is disposed between the mold insulating pattern 160 and the conductive lines 110, the etch stop film may include an insulating material. The etch stop film may include a material having etch selectivity with respect to the mold insulating pattern 160.

The mold insulating pattern 160 may include a first surface and a second surface that are opposite to each other in the third direction DR3. The second surface of the mold insulating pattern 160 may face (i.e., may be adjacent to) the conductive lines 110. For example, the first surface of the mold insulating pattern 160 may be the upper surface of the mold insulating pattern 160. The second surface of the mold insulating pattern 160 may be the bottom surface of the mold insulating pattern 160.

The mold insulating pattern 160 may include a plurality of wordline trenches WLT. The wordline trenches WLT may each extend longitudinally or lengthwise in the second direction DR2. Adjacent wordline trenches WLT may be spaced apart in the first direction DR1.

The wordline trenches WLT may intersect the conductive lines 110. In the semiconductor memory device according to some embodiments, the wordline trenches WLT may expose a plurality of conductive lines 110. For example, the wordline trenches WLT may expose the first and second conductive lines 110_1 and 110_2.

The bottom surfaces of the wordline trenches WLT may be defined by the conductive lines 110, the lower insulating film 105, and the mold insulating pattern 160. The sidewalls of each of the wordline trenches WLT may be defined by the mold insulating pattern 160.

The wordline trenches WLT may each include a first portion WLT_1 and a second portion WLT_2. In each wordline trench WLT, the first portions WLT_1 and the second portions WLT_2 of the wordline trenches WLT may be alternately defined along the second direction DR2. For example, the lower connection channel patterns CHB and the upper connection channel patterns CHU, which will be described later, may be disposed in the first portions WLT_1 of the wordline trenches WLT. The lower connection channel patterns CHB and the upper connection channel patterns CHU may not be disposed in the second portions WLT_2 of the wordline trench WLT.

A width W11 of the first portions WLT_1 of the wordline trenches WLT in the first direction DR1 may be different from a width W12 of the second portions WLT_2 of the wordline trenches WLT in the first direction DR1. For example, the width W11 of the first portions WLT_1 of the wordline trenches WLT may be greater than the width W12 of the second portions WLT_2 of the wordline trenches WLT.

Relative to the upper surface of the substrate 100, the height of the bottom surfaces of the first portions WLT_1 of the wordline trenches WLT may be less than the height of the bottom surfaces of the second portions WLT_2 of the wordline trenches WLT. For example, the bottom surfaces of the first portions WLT_1 may be lower than the bottom surfaces of the second portions WLT_2 relative to the upper surface of the substrate 100.

The lower connection channel patterns CHB may be disposed on the conductive lines 110. For example, the lower connection channel patterns CHB may be disposed on the first surfaces of the conductive lines 110. The lower connection channel patterns CHB may be connected to the conductive lines 110. For example, the lower connection channel patterns CHB may be electrically connected to the conductive lines 110. In an embodiment, the lower connection channel patterns CHB may contact the conductive lines 110. The term “contact,” or “in contact with,” as used herein, refers to a direct connection (i.e., physical touching) unless the context indicates otherwise.

In the semiconductor memory device according to some embodiments, a plurality of lower connection channel patterns CHB the are spaced apart from each other in the first direction DR1 may be connected to a single conductive line 110 extending lengthwise in the first direction DR1.

The lower connection channel patterns CHB may be disposed within the wordline trenches WLT, which extend in the second direction DR2. A plurality of lower connection channel patterns CHB may be disposed within a single wordline trench WLT to be spaced apart in the second direction DR2. For example, the lower connection channel patterns CHB may be arranged two-dimensionally along the first and second directions DR1 and DR2, which intersect each other.

The lower connection channel patterns CHB may include a first lower connection channel pattern CHB1 and a second lower connection channel pattern CHB2 that are spaced apart in the second direction DR2. For example, the first lower connection channel pattern CHB1 may be connected to the first conductive line 110_1 and may not be connected to the second conductive line 110_2. The second lower connection channel pattern CHB2 may be connected to the second conductive line 110_2 and may not be connected to the first conductive line 110_1. For example, the first lower connection channel pattern CHB1 may contact the first conductive line 110_1, without contacting the second conductive line 110_2. The second lower connection channel pattern CHB2 may contact the second conductive line 110_2, without contacting the first conductive line 110_1.

The lower connection channel patterns CHB may extend along the sidewalls and bottom surfaces of the wordline trenches WLT. For example, the lower connection channel patterns CHB may be in contact with the mold insulating pattern 160. In the semiconductor memory device according to some embodiments, the lower connection channel patterns CHB may have a substantially “U” shape in a cross-sectional view taken along the first direction DR1.

The lower connection channel patterns CHB may each include a horizontal portion CHB_H and a plurality of vertical portions CHB_V. The plurality of vertical portions CHB_V may include a first vertical portion CHB_V1 and a second vertical portion CHB_V2 that are spaced apart in the first direction DR1.

The horizontal portions CHB_H of the lower connection channel patterns CHB may extend along the bottom surfaces of the wordline trenches WLT. In FIGS. 4, 5, and 9, the horizontal portions CHB_H of the lower connection channel patterns CHB may extend in the first direction DR1. The horizontal portions CHB_H of the lower connection channel patterns CHB may be connected to the conductive lines 110. For example, the horizontal portions CHB_H may contact the conductive lines 110.

The first and second vertical portions CHB_V1 and CHB_V2 may be disposed on the sidewalls of the respective wordline trenches WLT. The first and second vertical portions CHB_V1 and CHB_V2 may extend along the sidewalls of the respective wordline trenches WLT.

The first and second vertical portions CHB_V1 and CHB_V2 may each protrude from the horizontal portion CHB_H of the corresponding lower connection channel pattern CHB in the third direction DR3. The first and second vertical portions CHB_V1 and CHB_V2 may each extend in the third direction DR3. The first and second vertical portions CHB_V1 and CHB_V2 may each be directly connected to the horizontal portion CHB_H of the corresponding lower connection channel pattern CHB.

For example, the vertical portions CHB_V of the lower connection channel patterns CHB may each include an extension portion CHB_VP1 extending in the third direction DR3 and an expansion portion CHB_VP2 extending in the first direction DR1. The expansion portion CHB_VP2 may be disposed at an upper end of its corresponding vertical portion CHB_V. The extension portion CHB_VP1 may be disposed between the expansion portion CHB_VP2 and the horizontal portion CHB_H of the corresponding lower connection channel pattern CHB. The width of the expansion portions CHB_VP2 of the vertical portions CHB_V of the lower connection channel patterns CHB in the first direction DR1 may be greater than the width of the extension portions CHB_VP1 of the vertical portions CHB_V of the lower connection channel patterns CHB in the first direction DR1. For example, in a cross-sectional view, the vertical portions CHB_V of the lower connection channel patterns CHB may have an “L” shape from a cross-sectional perspective.

Contrary to what is illustrated, the vertical portions CHB_V of the lower connection channel patterns CHB may not include the expansion portions CHB_VP2.

The lower connection channel patterns CHB may each serve as a channel region for the read transistors (“RTR” in FIG. 1) of two adjacent memory cells MC. For example, the first vertical portions CHB_V1 of a lower connection channel pattern CHB may serve as the channel region of the read transistor RTR of a first memory cell MC, and may also serve as the channel region of the read transistor RTR of a second memory cell adjacent to the first memory cell MC. For example, in the first portion WLT_1 of the wordline trench WLT, the two adjacent memory cells, each of which corresponds to the memory cell MC of FIG. 1. In each of the two adjacent memory cells, a single wordline is formed to drive the write transistor WTR and the read transistor RTR of the memory cell MC of FIG. 1, and the two adjacent memory cells share the write bitline WBL which corresponds to the first bitline 130.

The upper connection channel patterns CHU may be disposed on the lower connection channel patterns CHB. The upper connection channel patterns CHU may be disposed within spaces defined by the lower connection channel patterns CHB. The upper connection channel patterns CHU may be spaced apart from the lower connection channel patterns CHB in the third direction DR3. The upper connection channel patterns CHU may overlap the lower connection channel patterns CHB in the third direction DR3.

The lower connection channel patterns CHB may be disposed between the first wordlines 120 and the conductive lines 110 and between the second wordlines 125 and the conductive lines 110 in the third direction DR3. The lower connection channel patterns CHB may be disposed between the upper connection channel patterns CHU and the conductive lines 110 in the third direction DR3. The horizontal portions CHB_H of the lower connection channel patterns CHB may be disposed between the upper connection channel patterns CHU and the conductive lines 110 in the third direction DR3.

The upper connection channel patterns CHU may be disposed between the lower connection channel patterns CHB and the first wordlines 120 and between the lower connection channel patterns CHB and the second wordlines 125 in the third direction DR3.

The upper connection channel patterns CHU may each include a horizontal portion CHU_H and a plurality of vertical portions CHU_V. In the semiconductor memory device according to some embodiments, the plurality of vertical portions CHU_V may include a first vertical portion CHU_V1, a second vertical portion CHU_V2, and a third vertical portion CHU_V3 that are spaced apart in the first direction DR1.

The horizontal portions CHU_H of the upper connection channel patterns CHU may extend along the horizontal portions CHB_H of the lower connection channel patterns CHB. In FIGS. 4, 5, and 9, the horizontal portions CHU_H of the upper connection channel patterns CHU may extend in the first direction DR1.

The first, second, and third vertical portions CHU_V1, CHU_V2, and CHU_V3 may each protrude from the horizontal portion CHU_H of the corresponding upper connection channel pattern CHU in the third direction DR3. The first, second, and third vertical portions CHU_V1, CHU_V2, and CHU_V3 may each extend in the third direction DR3. The first and second vertical portions CHU_V1 and CHU_V2 may each be directly connected to the horizontal portion CHU_H of the corresponding upper connection channel pattern CHU. The third vertical portion CHU_V3 may be in contact with the horizontal portion CHU_H of the corresponding upper connection channel pattern CHU.

The first vertical portions CHU_V1 of the upper connection channel patterns CHU may extend along the first vertical portions CHB_V1 of the lower connection channel patterns CHB. In other words, the first vertical portions CHB_V1 of the lower connection channel patterns CHB may extend along the first vertical portions CHU_V1 of the upper connection channel patterns CHU.

The second vertical portions CHU_V2 of the upper connection channel patterns CHU may extend along the second vertical portions CHB_V2 of the lower connection channel patterns CHB. The third vertical portions CHU_V3 of the upper connection channel patterns CHU may be disposed between the first vertical portions CHU_V1 and the second vertical portions CHU_V2 of the upper connection channel patterns CHU. The third vertical portions CHU_V3 of the upper connection channel patterns CHU may be spaced apart from the first vertical portions CHU_V1 and the second vertical portions CHU_V2 of the upper connection channel patterns CHU in the first direction DR1.

In FIG. 10, a width W21 of the second vertical portions CHU_V2 of the upper connection channel patterns CHU in the second direction DR2 is illustrated as being greater than a width W23 of the third vertical portions CHU_V3 of the upper connection channel patterns CHU in the second direction DR2, but is not limited thereto. Additionally, a width W22 of the second vertical portions CHU_V2 of the upper connection channel patterns CHU in the first direction DR1 is illustrated as being greater than a width W24 of the third vertical portions CHU_V3 of the upper connection channel patterns CHU in the first direction DR1, but is not limited thereto.

The upper connection channel patterns CHU may each serve as a channel region for the write transistors WTR of two memory cells MC. The third vertical portion CHU_V3 and the horizontal portion CHU_H of an upper connection channel pattern CHU disposed below a first wordline 120 may serve as a channel region for the write transistor WTR of the first memory cell, and the third vertical portion CHU_V3 and the horizontal portion CHU_H of an upper connection channel pattern CHU disposed below a second wordline 125 may serve as a channel region for the write transistor WTR of the second memory cell adjacent to the first memory cell.

The first vertical portion CHU_V1 of the upper connection channel pattern CHU may be the drain terminal of the write transistor WTR of the first memory cell. The first vertical portion CHU_V1 of the upper connection channel pattern CHU may function as the gate of the read transistor RTR of the first memory cell. The second vertical portion CHU_V2 of the upper connection channel pattern CHU may be the drain terminal of the write transistor WTR of the second memory cell. For example, the first and second vertical portions CHU_V1 and CHU_V2 of the upper connection channel pattern CHU may correspond to the storage node gate SN_G of FIG. 1.

The lower connection channel patterns CHB and the upper connection channel patterns CHU may include one of silicon, germanium, silicon-germanium, a group III-V compound semiconductor, an oxide semiconductor material, a 2D material, or a combination thereof.

The silicon, germanium, or silicon-germanium that can be included in the lower connection channel patterns CHB and/or the upper connection channel patterns CHU may be in either a polycrystalline or monocrystalline state.

The group III-V compound semiconductor may include, for example, a binary, ternary, or quaternary compound formed by combining at least one group III element such as aluminum (Al), gallium (Ga), and indium (In) with a group V element such as phosphorus (P), arsenic (As), and antimony (Sb).

The oxide semiconductor material may include, for example, a metal oxide. In one example, the oxide semiconductor material may be an amorphous metal oxide. In another example, the oxide semiconductor material may be a polycrystalline metal oxide film. In yet another example, the oxide semiconductor material may be a combination of an amorphous metal oxide and a polycrystalline metal oxide. In still another example, the oxide semiconductor material may be a c-axis aligned crystalline (CAAC) metal oxide.

The oxide semiconductor material may include, for example, one of indium oxide, tin oxide, zinc oxide, an In-Zn-based oxide (IZO), a Sn-Zn-based oxide, an Al-Zn-based oxide, a Zn-Mg-based oxide, a Sn-Mg-based oxide, an In-Mg-based oxide, an In-Ga-based oxide (IGO), an In-Ga-Zn-based oxide (IGZO), an In-Al-Zn-based oxide, an In-Sn-Zn-based oxide, a Sn-Ga-Zn-based oxide, an Al-Ga-Zn-based oxide, a Sn-Al-Zn-based oxide, an In-Hf-Zn-based oxide, an In-La-Zn-based oxide, an In-Ce-Zn-based oxide, an In-Pr-Zn-based oxide, an In-Nd-Zn-based oxide, an In-Sm-Zn-based oxide, an In-Eu-Zn-based oxide, an In-Gd-Zn-based oxide, an In-Tb-Zn-based oxide, an In-Dy-Zn-based oxide, an In-Ho-Zn-based oxide, an In-Er-Zn-based oxide, an In-Tm-Zn-based oxide, an In-Yb-Zn-based oxide, an In-Lu-Zn-based oxide, an In-Sn-Ga-Zn-based oxide, an In-Hf-Ga-Zn-based oxide, an In-Al-Ga-Zn-based oxide, an In-Sn-Al-Zn-based oxide, an In-Sn-Hf-Zn-based oxide, and an In-Hf-Al-Zn-based oxide, but is not limited thereto.

The In-Ga-Zn-based oxide refers to an oxide containing In, Ga, and Zn as main components with an any ratio of In, Ga, and Zn. For example, the oxide semiconductor material may include indium gallium zinc oxide (IGZO, InₓGa_{y}Zn_{z}O). IGZO with an In:Ga:Zn ratio of 1:1:1 (In:Ga:Zn=1:1:1) may be the In-Ga-Zn-based oxide. A Ga-rich IGZO, which has a higher proportion of Ga and a lower proportion of In than IGZO (In:Ga:Zn=1:1:1), may also be the In-Ga-Zn-based oxide. Similarly, an In-rich IGZO, which has a higher proportion of In and a lower proportion of Ga than IGZO (In:Ga:Zn=1:1:1), may also be the In-Ga-Zn-based oxide.

The oxide semiconductor material has been described so far, taking IGZO as an example, but is not limited thereto. It is to be noted that the above description applies to an oxide semiconductor material including a metal oxide with three or more components. Additionally, when the oxide semiconductor material includes the In-Ga-Zn-based oxide, it may further include one or more doped metal elements in addition to In, Ga, and Zn.

In one example, a material of the lower connection channel patterns CHB and a material of the upper connection channel patterns CHU may be the same material. In another example, the lower connection channel patterns CHB and the upper connection channel patterns CHU may include different materials. Depending on whether performance or reliability is to be enhanced in the read transistor RTR and/or the write transistor WTR, the materials included in the lower connection channel patterns CHB and/or the upper connection channel patterns CHU may be variously combined.

The first wordlines 120 and the second wordlines 125 may be disposed on the upper connection channel patterns CHU. The first wordlines 120 and the second wordlines 125 may be disposed within the wordline trenches WLT.

The first wordlines 120 and the second wordlines 125 may each extend lengthwise in the second direction DR2. The first wordlines 120 may be spaced apart from the second wordlines 125 in the first direction DR1.

The first wordlines 120 and the second wordlines 125 may be disposed on the horizontal portions CHB_H of the lower connection channel patterns CHB. The first wordlines 120 and the second wordlines 125 may be disposed between the first vertical portions CHB_V1 and the second vertical portions CHB_V2 of the lower connection channel patterns CHB.

The first wordlines 120 and the second wordlines 125 may be disposed on the horizontal portions CHU_H of the upper connection channel patterns CHU. The first wordlines 120 may be disposed between the first vertical portions CHU_V1 and the third vertical portions CHU_V3 of the upper connection channel patterns CHU. The second wordlines 125 may be disposed between the second vertical portions CHU_V2 and the third vertical portions CHU_V3 of the upper connection channel patterns CHU.

The third vertical portions CHU_V3 of the upper connection channel patterns CHU may be disposed between the first wordlines 120 and the second wordlines 125. The first vertical portions CHU_V1 of the upper connection channel patterns CHU may be disposed between the first wordlines 120 and the first vertical portions CHB_V1 of the lower connection channel patterns CHB. The second vertical portions CHU_V2 of the upper connection channel patterns CHU may be disposed between the second wordlines 125 and the second vertical portions CHB_V2 of the lower connection channel patterns CHB. The horizontal portions CHU_H of the upper connection channel patterns CHU may be disposed between the first wordlines 120 and the horizontal portions CHB_H of the lower connection channel patterns CHB, and between the second wordlines 125 and the horizontal portions CHB_H of the lower connection channel patterns CHB.

The first wordlines 120 may each include a first sidewall 120_SW1 and a second sidewall 120_SW2 that are opposite to each other in the first direction DR1. The second wordlines 125 may each include a first sidewall 125_SW1 and a second sidewall 125_SW2 that are opposite to each other in the first direction DR1. The second sidewalls 120_SW2 of the first wordlines 120 may face the second sidewalls 125_SW2 of the second wordlines 125. For example, the second sidewalls 120_SW2 of the first wordlines 120 may be adjacent to the second sidewalls 125_SW2 of the second wordlines 125.

The first vertical portions CHU_V1 of the upper connection channel patterns CHU may extend along the first sidewalls 120_SW1 of the first wordlines 120 in the third direction DR3. The second vertical portions CHU_V2 of the upper connection channel patterns CHU may extend along the first sidewalls 125_SW1 of the second wordlines 125 in the third direction DR3. The third vertical portions CHU_V3 of the upper connection channel patterns CHU may extend along the second sidewalls 120_SW2 of the first wordlines 120 and the second sidewalls 125_SW2 of the second wordlines 125 in the third direction DR3. The third vertical portions CHU_V3 of the upper connection channel patterns CHU may be disposed between the second sidewalls 120_SW2 of the first wordlines 120 and the second sidewalls 125_SW2 of the second wordlines 125.

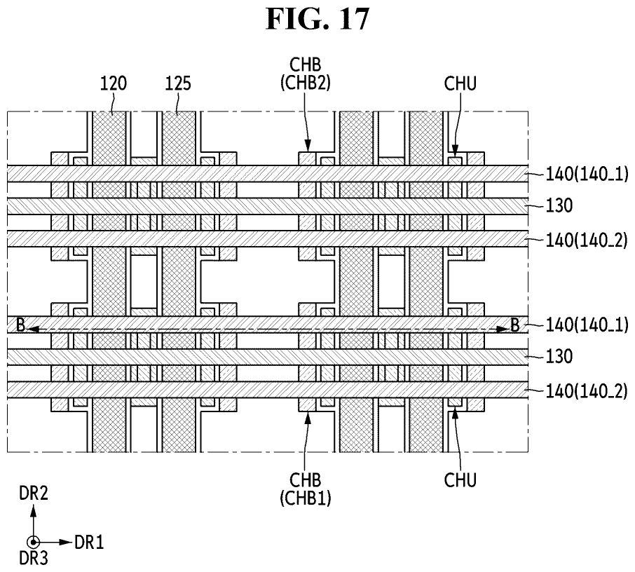

The first wordlines 120 and the second wordlines 125 may correspond to the wordline WL of FIG. 1, which is connected to both the gate terminals of the write transistor WTR and the read transistor RTR. For example, in FIG. 9, shown are two memory cells in the same wordline trench (e.g., the first portion WLT_1 of the wordline trench WLT). Each memory cell of FIG. 9 corresponds to the memory cell MC of FIG. 1. The wordlines WTR and RTR are merged to one of the first wordline 120 of a first memory cell and a second wordline 125 of a second memory cell. The first wordline 120 may operate as the wordlines WTR and RTR of the first memory cell. The second wordline 125 may operate as the wordlines WTR and RTR of the second memory cell. The first bitline 130 connected to the CHU may serve as the write bitline WBL, and may be shared by the two memory cells. The second bitline 140 connected to the first vertical portion CHB_V1 of the lower connection channel pattern CHB may serve as the read bitline RBL of the first memory cell, and the second bitline 140 connected to the second vertical portion CHB_V2 of the lower connection channel pattern CHB may serve as the read bitline RBL of the second memory cell. To improve a margin of a read operation, the second bitline 140 may be separated into first and second sub-bitlines 140_1 and 140_2 connected to the first vertical portion CHB_V1 of the lower connection channel pattern CHB and the second vertical portion CHB_V2 of the lower connection channel pattern CHB, respectively, as shown in FIG. 17.

The first wordlines 120 and the second wordlines 125 may each include a conductive material, for example, at least one of a doped semiconductor material, a conductive metal nitride, a conductive metal silicon nitride, a metal carbonitride, a conductive metal silicide, a conductive metal oxide, a 2D material, and a metal. The first wordlines 120 and the second wordlines 125 are illustrated as single films, but are not limited thereto.

Wordline capping patterns 128 may be disposed on the first wordlines 120 and the second wordlines 125. The wordline capping patterns 128 may be disposed between the first vertical portions CHU_V1 and the third vertical portions CHU_V3 of the upper connection channel patterns CHU and between the second vertical portions CHU_V2 and the third vertical portions CHU_V3 of the upper connection channel patterns CHU. The wordline capping patterns 128 may include an insulating material.

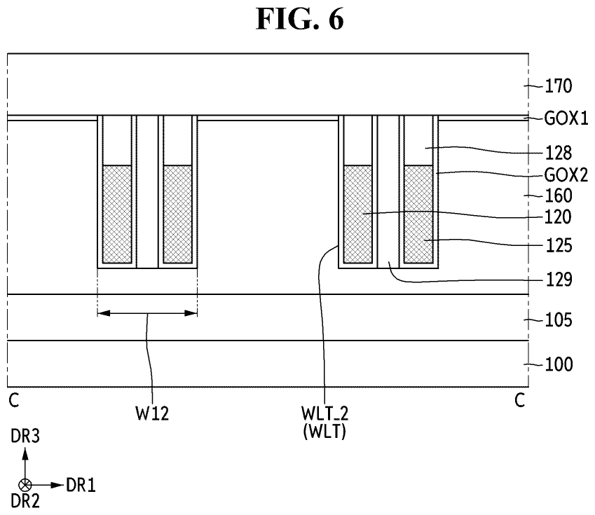

Wordline isolation patterns 129 may be disposed between the first wordlines 120 and the second wordlines 125 as shown in FIG. 6. The wordline isolation patterns 129 may be disposed on the mold insulating pattern 160. The wordline isolation patterns 129 may be disposed between the third vertical portions CHU_V3 of adjacent upper connection channel patterns CHU in the second direction DR2 as shown in FIG. 7. The wordline isolation patterns 129 may include an insulating material.

First gate insulating patterns GOX1 may be disposed between the lower connection channel patterns CHB and the upper connection channel patterns CHU. The first gate insulating patterns GOX1 may extend along spaces between the lower connection channel patterns CHB and the upper connection channel patterns CHU. The first gate insulating patterns GOX1 are illustrated as extending along the upper surface of the mold insulating pattern 160, but are not limited thereto.

Second gate insulating patterns GOX2 may be disposed between the upper connection channel patterns CHU and the first wordlines 120 and between the upper connection channel patterns CHU and the second wordlines 125. The second gate insulating patterns GOX2 may extend along spaces between the upper connection channel patterns CHU and the first wordlines 120. The second gate insulating patterns GOX2 may further extend along spaces between the upper connection channel patterns CHU and the second wordlines 125. The second gate insulating patterns GOX2 are illustrated as further extending along spaces between the wordline capping patterns 128 and the vertical portions CHU_V of the upper connection channel patterns CHU, but are not limited thereto.

The first gate insulating patterns GOX1 and the second gate insulating patterns GOX2 may each include silicon oxide, silicon oxynitride, a high-k dielectric material with a greater dielectric constant than silicon oxide, or a combination thereof. The high-k dielectric material may include a metal oxide or a metal oxynitride. For example, the high-k dielectric material may include at least one of hafnium oxide, hafnium silicon oxide, hafnium silicon oxynitride, hafnium tantalum oxide, hafnium titanium oxide, hafnium zirconium oxide, zirconium oxide, and aluminum oxide, but is not limited thereto.

An upper insulating film 170 may be disposed on the lower connection channel patterns CHB and the upper connection channel patterns CHU. The upper insulating film 170 may be disposed on the upper surface of the mold insulating pattern 160. The upper insulating film 170 may include an insulating material.

The first bitlines 130 and the second bitlines 140 may each be spaced apart from the conductive lines 110 in the third direction DR3. The first bitlines 130 and the second bitlines 140 may be disposed on the lower connection channel patterns CHB and the upper connection channel patterns CHU. The first bitlines 130 and the second bitlines 140 may be disposed on the first wordlines 120 and the second wordlines 125. The first wordlines 120 and the second wordlines 125 may be disposed between the first bitlines 130 and the conductive lines 110 and between the second bitlines 140 and the conductive lines 110.

The first bitlines 130 and the second bitlines 140 may each extend in the first direction DR1. The first bitlines 130 may be spaced apart from the second bitlines 140 in the second direction DR2. In the semiconductor memory device according to some embodiments, a single first bitline 130 and a single second bitline 140 may be disposed on lower connection channel patterns CHB arranged in the first direction DR1.

The first bitlines 130 may be connected to the upper connection channel patterns CHU. For example, the first bitlines 130 may be connected to the third vertical portions CHU_V3 of the upper connection channel patterns CHU.

The second bitlines 140 may be connected to the lower connection channel patterns CHB. For example, the second bitlines 140 may be connected to the first vertical portions CHB_V1 and the second vertical portions CHB_V2 of the lower connection channel patterns CHB. By connecting each single second bitline 140 and the first vertical portions CHB_V1 and the second vertical portions CHB_V2 of the lower connection channel patterns CHB, the area of the memory cell array may be reduced, and the manufacturing process may be simplified.

The first bitlines 130 and the second bitlines 140 may each include an extension extending in the first direction DR1 and a protrusion extending toward the lower connection channel patterns CHB or the upper connection channel patterns CHU. The protrusions of the first bitlines 130 may be connected to the upper connection channel patterns CHU. The protrusions of the second bitlines 140 may be connected to the lower connection channel patterns CHB. Contrary to what is illustrated, the first bitlines 130 and the second bitlines 140 may not include protrusions.

The first bitlines 130 may correspond to the write bitline WBL of the write transistor WTR of FIG. 1. The second bitlines 140 may correspond to the read bitline RBL of the read transistor RTR of FIG. 1. For example, each first bitline of the first bitlines 130 may correspond to the write bitline WBL of the memory cell MC in FIG. 1, and each second bitline of the second bitlines 140 may correspond to the read bitline RBL of the memory cell MC in FIG. 1.

The first bitlines 130 and the second bitlines 140 may each include a conductive material, for example, at least one of a doped semiconductor material, a conductive metal nitride, a conductive metal silicon nitride, a metal carbonitride, a conductive metal silicide, a conductive metal oxide, a 2D material, or a metal. The first bitlines 130 and the second bitlines 140 are illustrated as single films, but are not limited thereto.

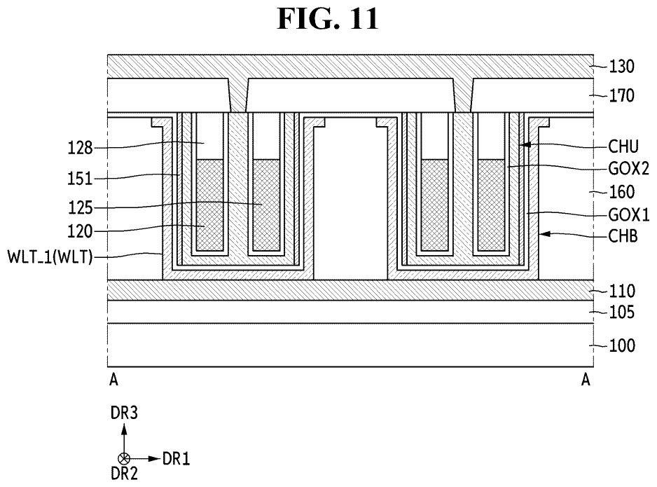

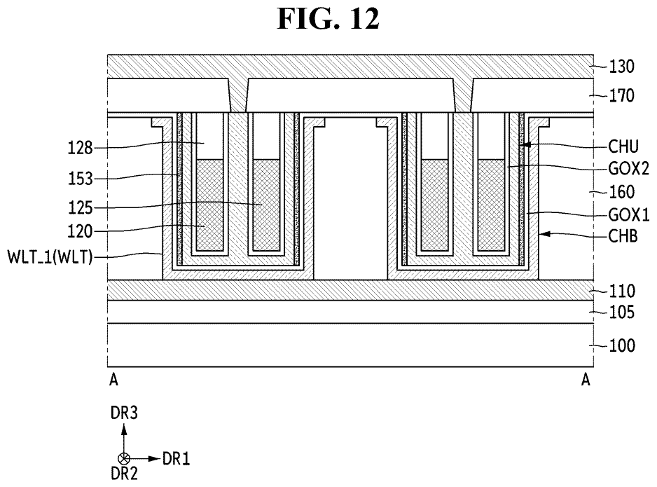

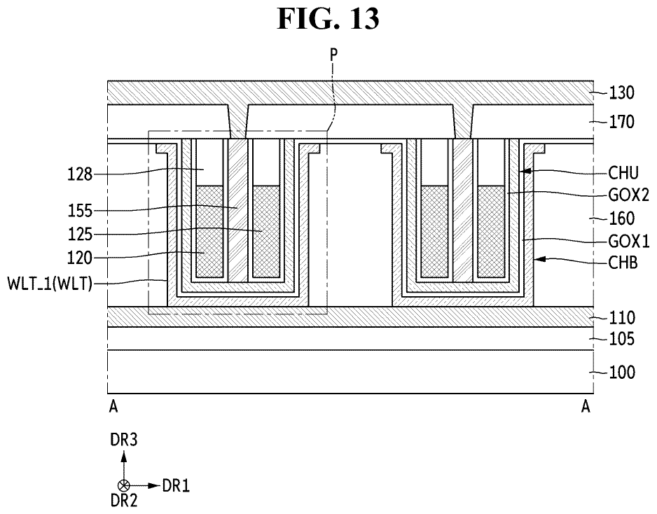

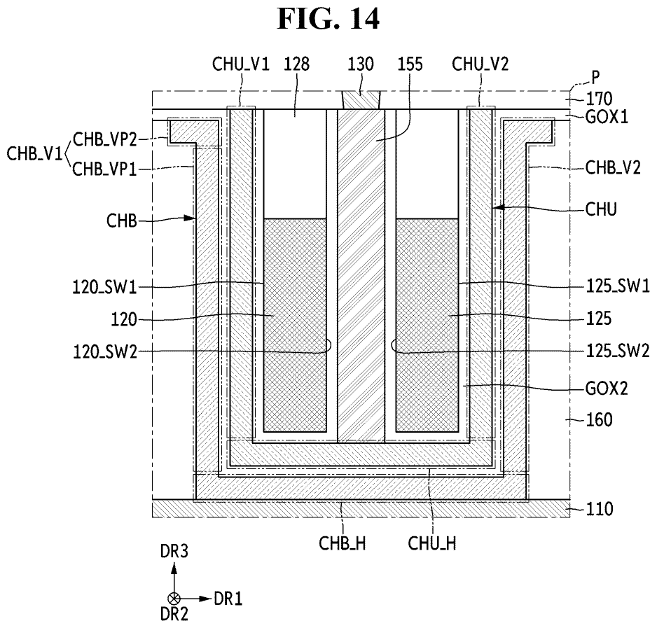

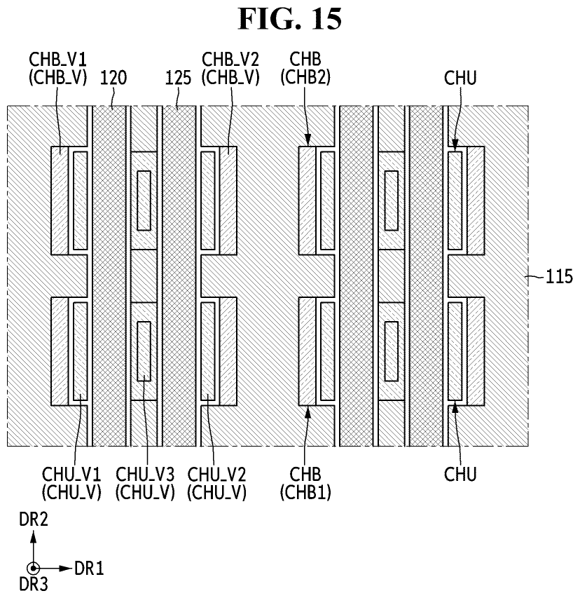

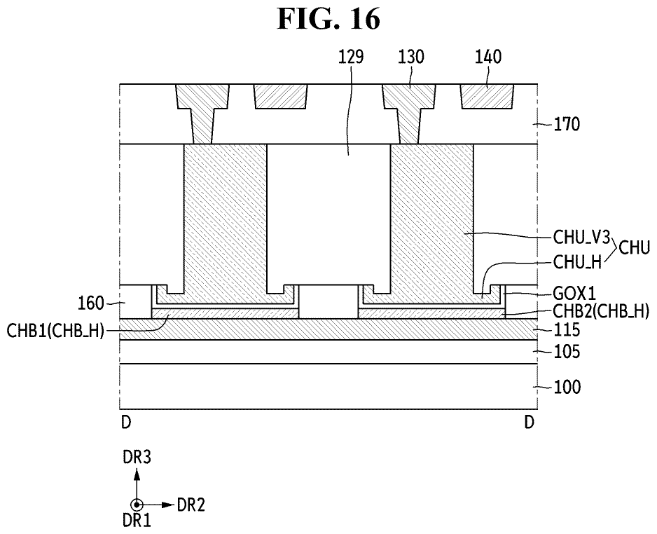

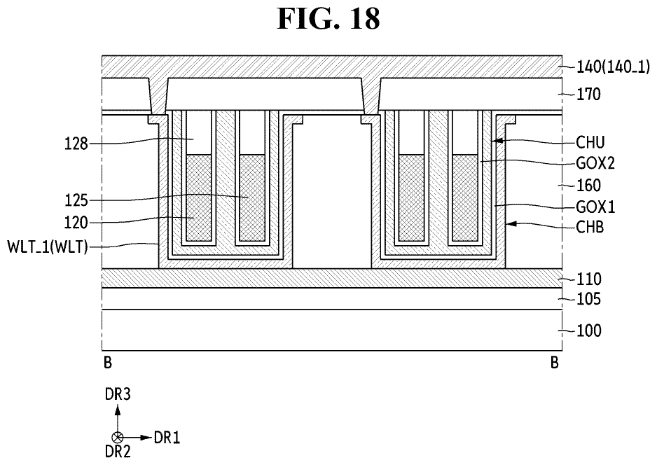

FIG. 11 is a diagram illustrating a semiconductor memory device according to some embodiments. FIG. 12 is a diagram illustrating a semiconductor memory device according to some embodiments. FIGS. 13 and 14 are diagrams illustrating a semiconductor memory device according to some embodiments. FIGS. 15 and 16 are diagrams illustrating a semiconductor memory device according to some embodiments. FIGS. 17 and 18 are diagrams illustrating a semiconductor memory device according to some embodiments. For convenience, the following description focuses on the differences from the embodiments of FIGS. 1 through 10.

Referring to FIG. 11, the semiconductor memory device according to some embodiments may further include insertion channel metal patterns 151.

The insertion channel metal patterns 151 may be disposed between first wordlines 120 and first vertical portions CHB_V1 of lower connection channel patterns CHB, and between second wordlines 125 and second vertical portions CHB_V2 of the lower connection channel patterns CHB.

For example, the insertion channel metal patterns 151 may be disposed between the first vertical portions CHB_V1 of the lower connection channel patterns CHB and first vertical portions CHU_V1 of upper connection channel patterns CHU, and between the second vertical portions CHB_V2 of the lower connection channel patterns CHB and second vertical portions CHU_V2 of the upper connection channel patterns CHU. The insertion channel metal patterns 151 may not be disposed between the first wordlines 120 and third vertical portions CHU_V3 of the upper connection channel patterns CHU, nor between the second wordlines 125 and the third vertical portions CHU_V3 of the upper connection channel patterns CHU.

The insertion channel metal patterns 151 may extend along the first vertical portions CHU_V1 of the upper connection channel patterns CHU in the third direction DR3. The insertion channel metal patterns 151 may extend along the second vertical portions CHU_V2 of the upper connection channel patterns CHU in the third direction DR3. For example, the insertion channel metal patterns 151 may be in contact with the upper connection channel patterns CHU.

The insertion channel metal patterns 151 may include a conductive material, such as a metal.

As the insertion channel metal patterns 151 are formed along the first vertical portions CHU_V1 and the second vertical portions CHU_V2 of the upper connection channel patterns CHU, Schottky barriers may be formed between the insertion channel metal patterns 151 and the first vertical portions CHU_V1 of the upper connection channel patterns CHU, and between the insertion channel metal patterns 151 and the second vertical portions CHU_V2 of the upper connection channel patterns CHU. Accordingly, during a program operation, the charge stored in the first vertical portions CHU_V1 and the second vertical portions CHU_V2 of the upper connection channel patterns CHU can be retained for a longer period of time. Therefore, the performance and reliability of the semiconductor memory device according to some embodiments can be enhanced.

Referring to FIG. 12, the semiconductor memory device according to some embodiments may further include insertion ferroelectric material patterns 153.

The insertion ferroelectric material patterns 153 may be disposed between first wordlines 120 and first vertical portions CHB_V1 of lower connection channel patterns CHB, and between second wordlines 125 and second vertical portions CHB_V2 of the lower connection channel patterns CHB.

For example, the insertion ferroelectric material patterns 153 may be disposed between the first vertical portions CHB_V1 of the lower connection channel patterns CHB and first vertical portions CHU_V1 of upper connection channel patterns CHU, and between the second vertical portions CHB_V2 of the lower connection channel patterns CHB and second vertical portions CHU_V2 of the upper connection channel patterns CHU. The insertion ferroelectric material patterns 153 may not be disposed between the first wordlines 120 and third vertical portions CHU_V3 of the upper connection channel patterns CHU, nor between the second wordlines 125 and the third vertical portions CHU_V3 of the upper connection channel patterns CHU.

The insertion ferroelectric material patterns 153 may extend along the first vertical portions CHU_V1 of the upper connection channel patterns CHU in the third direction DR3. The insertion ferroelectric material patterns 153 may extend along the second vertical portions CHU_V2 of the upper connection channel patterns CHU in the third direction DR3. For example, the insertion ferroelectric material patterns 153 may be in contact with the upper connection channel patterns CHU.

The insertion ferroelectric material patterns 153 may include a ferroelectric material.

The insertion ferroelectric material patterns 153 may include at least one of hafnium oxide, hafnium zirconium oxide, barium strontium titanium oxide, barium titanium oxide, and lead zirconium titanium oxide. For example, hafnium zirconium oxide may be a material in which zirconium (Zr) is doped into hafnium oxide. In another example, hafnium zirconium oxide may be a compound of hafnium (Hf), Zr, and oxygen (O). However, these ferroelectric materials are merely examples, and do not limit the technical scope of the present disclosure.

The insertion ferroelectric material patterns 153 may further include a dopant. For example, the dopant may include at least one of aluminum(Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the insertion ferroelectric material patterns 153 may vary depending on the ferroelectric material used in the insertion ferroelectric material patterns 153.

If the insertion ferroelectric material patterns 153 include hafnium oxide, the dopant included in the insertion ferroelectric material patterns 153 may include at least one of Gd, Si, Zr, Al, and Y.

If Al is used as the dopant, the insertion ferroelectric material patterns 153 may include 3 to 8 atomic percent (at %) of Al. Here, the percentage of the dopant may be based on the sum of Hf and Al. If Si is used as the dopant, the insertion ferroelectric material patterns 153 may include 2 to 10 at % of Si. If Y is used as the dopant, the insertion ferroelectric material patterns 153 may include 2 to 10 at% of Y. If Gd is used as the dopant, the insertion ferroelectric material patterns 153 may include 1 to 7 at % of Gd. If Zr is used as a dopant, the insertion ferroelectric material patterns 153 may include 50 to 80 at % of Zr.

The insertion ferroelectric material patterns 153 may have a thickness sufficient to exhibit ferroelectric properties. The thickness of the insertion ferroelectric material patterns 153 may be, for example, 0.5 to 10 nm, but is not limited thereto. Since the critical thickness for exhibiting ferroelectric properties varies from ferroelectric material to ferroelectric material, the thickness of the insertion ferroelectric material patterns 153 may vary depending on the ferroelectric material used.

In one example, the insertion ferroelectric material patterns 153 may each include a single ferroelectric material layer. In another example, the insertion ferroelectric material patterns 153 may each include multiple ferroelectric material layers spaced apart from each other. For example, the insertion ferroelectric material patterns 153 may have a stacked structure in which multiple ferroelectric material layers and at least one dielectric material layer are alternately stacked.

As the insertion ferroelectric material patterns 153 are formed along the first vertical portions CHU_V1 and the second vertical portions CHU_V2 of the upper connection channel patterns CHU, Schottky barriers may be formed between the insertion ferroelectric material patterns 153 and the first vertical portions CHU_V1 of the upper connection channel patterns CHU, and between the insertion ferroelectric material patterns 153 and the second vertical portions CHU_V2 of the upper connection channel patterns CHU. Therefore, the performance and reliability of the semiconductor memory device according to some embodiments can be enhanced.

Referring to FIGS. 13 and 14, the semiconductor memory device according to some embodiments may further include connection channel conductive patterns 155 that are disposed between first wordlines 120 and second wordlines 125.

The connection channel conductive patterns 155 may be disposed between first vertical portions CHU_V1 and second vertical portions CHU_V2 of upper connection channel patterns CHU. The connection channel conductive patterns 155 may be spaced apart from the first vertical portions CHU_V1 and the second vertical portions CHU_V2 of the upper connection channel patterns CHU in the first direction DR1. The first wordlines 120 may be disposed between the connection channel conductive patterns 155 and the first vertical portions CHU_V1 of the upper connection channel patterns CHU. The second wordlines 125 may be disposed between the connection channel conductive patterns 155 and the second vertical portions CHU_V2 of the upper connection channel patterns CHU.

The connection channel conductive patterns 155 may protrude in the third direction DR3 from horizontal portions CHU_H of the upper connection channel patterns CHU. The connection channel conductive patterns 155 may be connected to the horizontal portions CHU_H of the upper connection channel patterns CHU. For example, the connection channel conductive patterns 155 may be in contact with the horizontal portions CHU_H of the upper connection channel patterns CHU.

First bitlines 130 may be connected to the connection channel conductive patterns 155. The connection channel conductive patterns 155 may be electrically connected to the upper connection channel patterns CHU.

The upper connection channel patterns CHU may not include third vertical portions (“CHU_V3” in FIG. 9). The connection channel conductive patterns 155 may be formed at the positions of the third vertical portions CHU_V3.

In an embodiment, a material of the connection channel conductive patterns 155 may be different from a material of the upper connection channel patterns CHU. For example, the connection channel conductive patterns 155 may include a conductive material, for example, at least one of a doped semiconductor material, a conductive metal nitride, a conductive metal silicon nitride, a metal carbonitride, a conductive metal silicide, a conductive metal oxide, and a metal. In one example, the connection channel conductive patterns 155 may include a metal.

Referring to FIGS. 15 and 16, the semiconductor memory device according to some embodiments may include a conductive plate 115.

The conductive plate 115 may be disposed on a lower insulating film 105. The conductive plate 115 may be disposed on a substrate 100 in place of conductive lines 110.

The conductive plate 115 may be connected to a ground voltage. The conductive plate 115 may be connected to the source terminals of read transistors (“RTR” in FIG. 1).

Adjacent lower connection channel patterns CHB in the second direction DR2 may be connected to the conductive plate 115. For example, a first lower connection channel pattern CHB1 and a second lower connection channel pattern CHB2, which are spaced apart from each other in the second direction DR2, may be connected to the conductive plate 115. By forming the conductive plate 115 in a memory cell array where memory cells (“MC” in FIG. 1) are disposed, the manufacturing process may be simplified.

Referring to FIGS. 17 and 18, in the semiconductor memory device according to some embodiments, a single first bitline 130 and a plurality of second bitlines 140 may be disposed on lower connection channel patterns CHB and extend in the first direction DR1.

The plurality of second bitlines 140 may include a first sub-bitline 140_1 and a second sub-bitline 140_2. The first and second sub-bitlines 140_1 and 140_2 may each extend in the first direction DR1.

The first sub-bitline 140_1 may be spaced apart from the second sub-bitline 140_2 in the second direction DR2. The first bitline 130 may be disposed between the first and second sub-bitlines 140_1 and 140_2.

The first sub-bitline 140_1 may be connected to first vertical portions (“CHB_V1” in FIG. 9) of the lower connection channel patterns CHB but may not be connected to second vertical portions (“CHB_V2” in FIG. 9) of the lower connection channel pattern CHB. The second sub-bitline 140_2 may be connected to the second vertical portion CHB_V2 of the lower connection channel patterns CHB but may not be connected to the first vertical portions CHB_V1 of the lower connection channel patterns CHB.

By connecting the drain terminals of the read transistors (“RTR” in FIG. 1) of adjacent memory cells to different second bitlines 140, the sensing margin of a memory cell array can be improved.

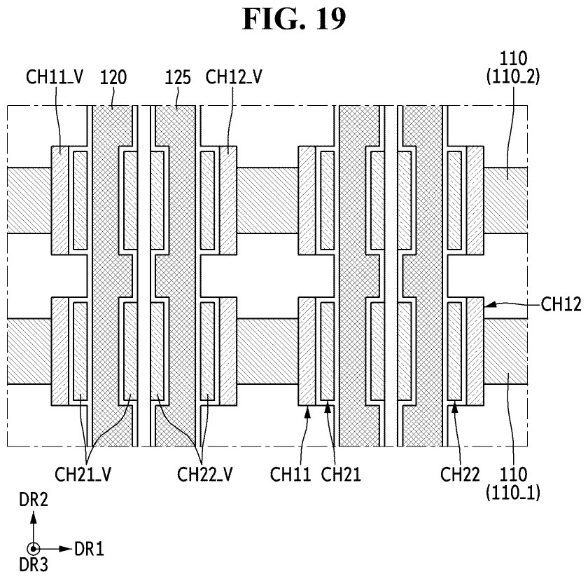

FIGS. 19 through 23 are diagrams illustrating a semiconductor memory device according to some embodiments. For convenience, the following description focuses on the differences from the embodiments described with reference to FIGS. 1 through 10.

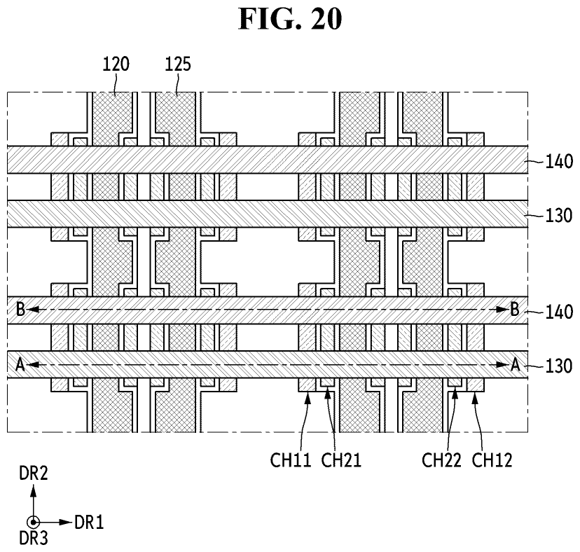

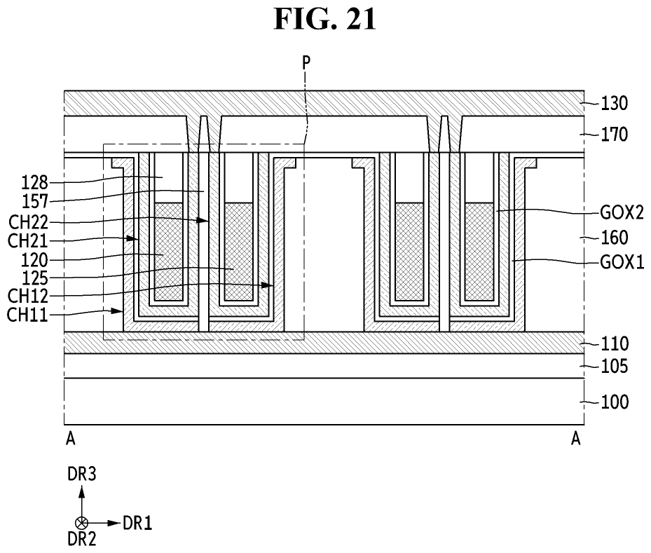

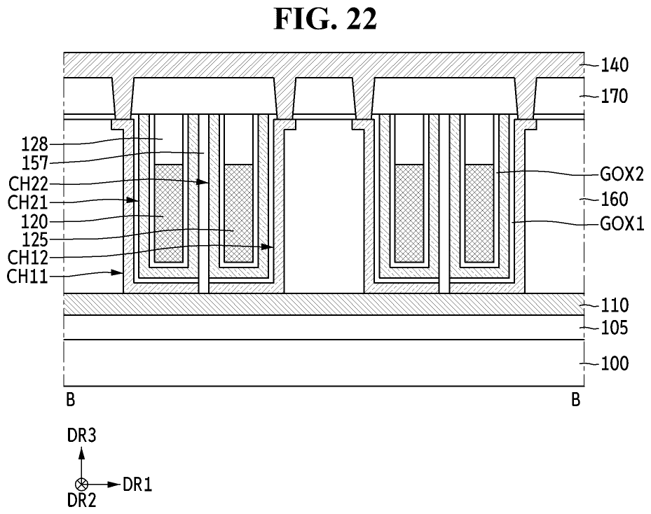

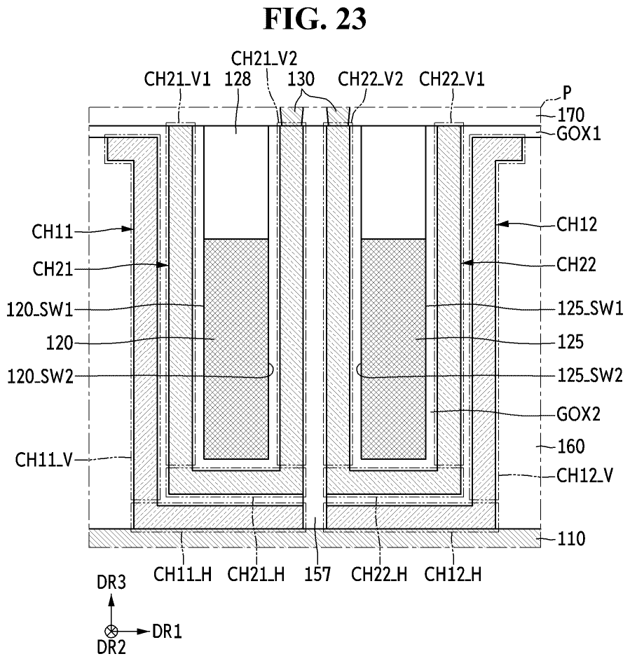

For reference, FIGS. 19 and 20 are layout diagrams illustrating a semiconductor memory device according to some embodiments. FIGS. 21 and 22 are cross-sectional views taken along lines A-A and B-B, respectively, of FIG. 20. FIG. 23 is an enlarged cross-sectional view of portion P in FIG. 21.

Referring to FIGS. 19 through 23, the semiconductor memory device according to some embodiments may include conductive lines 110, first lower channel patterns CH11, second lower channel patterns CH12, first upper channel patterns CH21, second upper channel patterns CH22, first wordlines 120, second wordlines 125, first bitlines 130, and second bitlines 140.

The first lower channel patterns CH11 and the second lower channel patterns CH12 may be disposed on the conductive lines 110. The first lower channel patterns CH11 and the second lower channel patterns CH12 may be connected to the corresponding conductive lines 110.

The first lower channel patterns CH11 may be arranged in the second direction DR2. The second lower channel patterns CH12 may be arranged in the second direction DR2. The first lower channel patterns CH11 and the second lower channel patterns CH12 may be alternately arranged in the first direction DR1.

In the semiconductor memory device according to some embodiments, the first lower channel patterns CH11 and the second lower channel patterns CH12 may each have an “L” shape in a cross-sectional view taken along the first direction DR1.

The first lower channel patterns CH11 may each include a horizontal portion CH11_H and a vertical portion CH11_V. The vertical portions CH11_V of the first lower channel patterns CH11 may protrude in the third direction DR3 from the horizontal portions CH11_H of the first lower channel patterns CH11. The vertical portions CH11_V of the first lower channel patterns CH11 may be directly connected to the horizontal portions CH11_H of the first lower channel patterns CH11.

The second lower channel patterns CH12 may each include a horizontal portion CH12_H and a vertical portion CH12_V. The vertical portions CH12_V of the second lower channel patterns CH12 may protrude in the third direction DR3 from the horizontal portions CH12_H of the second lower channel patterns CH12. The vertical portions CH12_V of the second lower channel patterns CH12 may be directly connected to the horizontal portions CH12_H of the second lower channel patterns CH12.

The horizontal portions CH11_H of the first lower channel patterns CH11 and the horizontal portions CH12_H of the second lower channel patterns CH12 may be connected to the conductive lines 110. The first lower channel patterns CH11 and the second lower channel patterns CH12 may serve as channel regions for the read transistors (“RTR” in FIG. 1) of memory cells (“MC” in FIG. 1).

Lower connection channel patterns (“CHB” in FIG. 4) may be divided into the first lower channel patterns CH11 and the second lower channel patterns CH12.

The first upper channel patterns CH21 may be disposed on the first lower channel patterns CH11. The first upper channel patterns CH21 may overlap the first lower channel patterns CH11 in the third direction DR3.

The second upper channel patterns CH22 may be disposed on the second lower channel patterns CH12. The second upper channel patterns CH22 may overlap the second lower channel patterns CH12 in the third direction DR3.

In the semiconductor memory device according to some embodiments, the first upper channel patterns CH21 and the second upper channel patterns CH22 may each have a “U” shape in a cross-sectional view taken along the first direction DR1.

The first upper channel patterns CH21 may each include a horizontal portion CH21_H and a plurality of vertical portions CH21_V. The plurality of vertical portions CH21_V may include a first vertical portion CH21_V1 and a second vertical portion CH21_V2. The first and second vertical portions CH21_V1 and CH21_V2 may protrude in the third direction DR3 from the horizontal portion CH21_H of the corresponding first upper channel pattern CH21. The first and second vertical portions CH21_V1 and CH21_V2 may be directly connected to the horizontal portion CH21_H of the corresponding first upper channel pattern CH21.

The second upper channel patterns CH22 may each include a horizontal portion CH22_H and a plurality of vertical portions CH22_V. The plurality of vertical portions CH22_V may include a first vertical portion CH22_V1 and a second vertical portion CH22_V2. The first and second vertical portions CH22_V1 and CH22_V2 may protrude in the third direction DR3 from the horizontal portion CH22_H of the corresponding second upper channel pattern CH22. The first and second vertical portions CH22_V1 and CH2 2_V2 may be directly connected to the horizontal portion CH22_H of the corresponding second upper channel pattern CH22.

The first wordlines 120 may be disposed between the first vertical portions CH21_V1 and the second vertical portions CH21_V2 of the first upper channel patterns CH21. The second wordlines 125 may be disposed between the first vertical portions CH22_V1 and the second vertical portions CH22_V2 of the second upper channel patterns CH22.

The first upper channel patterns CH21 and the second upper channel patterns CH22 may serve as channel regions for the write transistors (“WTR” in FIG. 1) of memory cells (“MC” in FIG. 1). For example, the horizontal portions CH21_H and the second vertical portions CH21_V2 of the first upper channel patterns CH21 may serve as channel regions for the write transistors WTR. Additionally, the horizontal portions CH22_H and the second vertical portions CH22_V2 of the second upper channel patterns CH22 may serve as channel regions for the write transistors WTR. The first vertical portions CH21_V1 of the first upper channel patterns CH21 and the first vertical portions CH22_V1 of the second upper channel patterns CH22 may be the drain terminals of the write transistors WTR. For example, the first vertical portions CH21_V1 of the first upper channel patterns CH21 and the first vertical portions CH22_V1 of the second upper channel patterns CH22 may correspond to the storage node gate SN_G in FIG. 1.

Upper connection channel patterns (“CHU” in FIG. 4) may be divided into the first upper channel patterns CH21 and the second upper channel patterns CH22.

The first lower channel patterns CH11 and the second lower channel patterns CH12 may include one of silicon, germanium, silicon-germanium, a group III-V compound semiconductor, an oxide semiconductor material, a 2D material, or a combination thereof. The first upper channel patterns CH21 and the second upper channel patterns CH22 may include one of silicon, germanium, silicon-germanium, a group III-V compound semiconductor, an oxide semiconductor material, a two-dimensional material, or a combination thereof.

By separating the first lower channel patterns CH11 and the second lower channel patterns CH12 from each other, interference between adjacent memory cells MC may be reduced. Therefore, the performance and reliability of the semiconductor memory device according to some embodiments can be enhanced.

Channel isolation insulating patterns 157 may be disposed between the first lower channel patterns CH11 and the second lower channel patterns CH12 and between the first upper channel patterns CH21 and the second upper channel patterns CH22. The channel isolation insulating patterns 157 may be disposed between the first wordlines 120 and the second wordlines 125. The channel isolation insulating patterns 157 may include an insulating material.

First gate insulating patterns GOX1 may be disposed between the first lower channel patterns CH11 and the first upper channel patterns CH21 and between the second lower channel patterns CH12 and the second upper channel patterns CH22. Second gate insulating patterns GOX2 may be disposed between the first upper channel patterns CH21 and the first wordlines 120 and between the second upper channel patterns CH22 and the second wordlines 125.

The first bitlines 130 may be connected to the first upper channel patterns CH21 and the second upper channel patterns CH22. For example, the first bitlines 130 may be connected to the second vertical portions CH21_V2 of the first upper channel patterns CH21 and the second vertical portions CH22_V2 of the second upper channel patterns CH22.

The protrusions of each first bitlines 130 connected to the second vertical portions CH21_V2 of the first upper channel patterns CH21 and the second vertical portions CH22_V2 of the second upper channel patterns CH22 are illustrated as being separate, but are not limited thereto. Alternatively, the protrusions of each first bitline 130 may be connected to both the second vertical portions CH21_V2 of the first upper channel patterns CH21 and the second vertical portions CH22_V2 of the second upper channel patterns CH22.

The second bitlines 140 may be connected to the first lower channel patterns CH11 and the second lower channel patterns CH12. For example, the second bitlines 140 may be connected to the vertical portions CH11_V of the first lower channel patterns CH11 and the vertical portions CH12_V of the second lower channel patterns CH12.

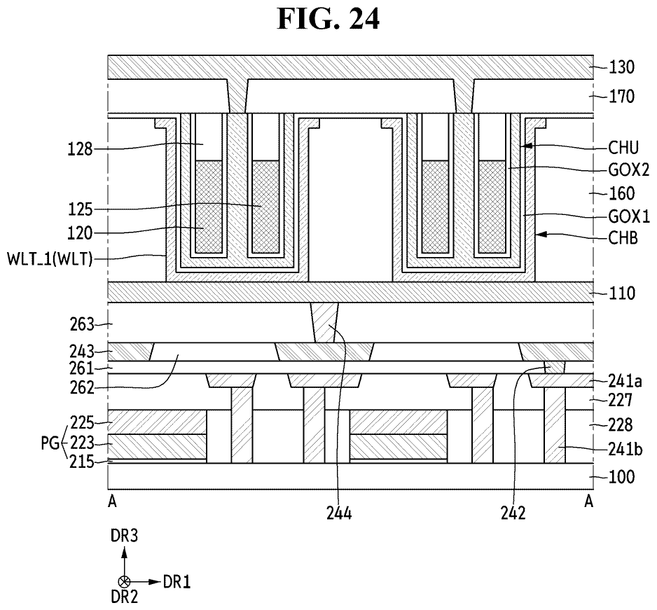

FIG. 24 is a diagram illustrating a semiconductor memory device according to some embodiments. For convenience, the following description focuses on the differences from the embodiments described with reference to FIGS. 1 through 10.

Referring to FIG. 24, the semiconductor memory device according to some embodiments may further include a peripheral gate structure PG.

The peripheral gate structure PG may be disposed on a substrate 100. The peripheral gate structure PG may be included in sensing transistors, transfer transistors, or driving transistors. The types of transistors disposed in a cell array region and a peripheral circuit region may vary depending on the design layout of the semiconductor memory device according to some embodiments.

The peripheral gate structure PG may include a peripheral gate insulating film 215, a lower peripheral conductive pattern 223, and an upper peripheral conductive pattern 225. The peripheral gate insulating film 215 may include a silicon oxide film, a silicon oxynitride film, a high-k insulating film with a greater dielectric constant than silicon oxide, or a combination thereof. The high-k insulating film may include, for example, at least one of a metal oxide, a metal oxynitride, a metal silicon oxide, or a metal silicon oxynitride, but is not limited thereto.

The lower and upper peripheral conductive patterns 223 and 225 may each include a conductive material. For example, the lower and upper peripheral conductive patterns 223 and 225 may each include at least one of a doped semiconductor material, a conductive metal nitride, a conductive metal silicon nitride, a metal carbonitride, a conductive metal silicide, a conductive metal oxide, a 2D material, or a metal. The peripheral gate structure PG is illustrated as including multiple conductive patterns, but is not limited thereto.

A first lower peripheral insulating film 227 and a second lower peripheral insulating film 228 may be disposed on the substrate 100. The first and second lower peripheral insulating films 227 and 228 may each include an insulating material.

First peripheral wiring lines 241a and peripheral contact plugs 241b may be disposed within the first and second lower peripheral insulating films 227 and 228. The first peripheral wiring lines 241a and the peripheral contact plugs 241b are illustrated as separate layers, but are not limited thereto. The boundaries between the first peripheral wiring lines 241a and the peripheral contact plugs 241b may not be distinguishable. The first peripheral wiring lines 241a and the peripheral contact plugs 241b may each include a conductive material.

A first upper peripheral insulating film 261 and a second upper peripheral insulating film 262 may be disposed on the first peripheral wiring lines 241a and the peripheral contact plugs 241b. The first and second upper peripheral insulating films 261 and 262 may each include an insulating material.

Second peripheral wiring lines 243 and peripheral via plugs 242 may be disposed on the first peripheral wiring lines 241a. The peripheral via plugs 242 may be disposed within the first upper peripheral insulating film 261. The second peripheral wiring lines 243 may be disposed within the second upper peripheral insulating film 262.

The second peripheral wiring lines 243 and the peripheral via plugs 242 may be connected to the first peripheral wiring lines 241a. The peripheral via plugs 242 may connect the first peripheral wiring lines 241a and the second peripheral wiring lines 243. The second peripheral wiring lines 243 and the peripheral via plugs 242 may each include a conductive material. The second peripheral wiring lines 243 and the peripheral via plugs 242 are illustrated as separate layers, but are not limited thereto. The boundaries between the second peripheral wiring lines 243 and the peripheral via plugs 242 may not be distinguishable.

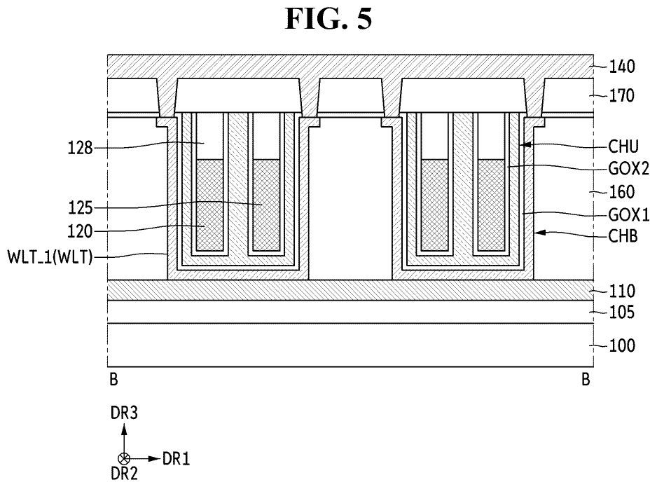

The conductive lines 110, the lower connection channel patterns CHB, the upper connection channel patterns CHU, the first wordlines 120, the second wordlines 125, the first bitlines 130, and second bitlines (“140” in FIG. 5) may be disposed on the peripheral gate structure PG.

Cell connection plugs 244 may be disposed within a third upper peripheral insulating film 263. The cell connection plugs 244 may be connected to the second peripheral wiring lines 243. The cell connection plugs 244 include a conductive material. The third upper peripheral insulating film 263 includes an insulating material.

The conductive lines 110 may be disposed on the cell connection plugs 244. The conductive lines 110 may be connected to the cell connection plugs 244. Although not illustrated, the first bitlines 130, the second bitlines 140, the first wordlines 120, and the second wordlines 125 may be connected to the second peripheral wiring lines 243.

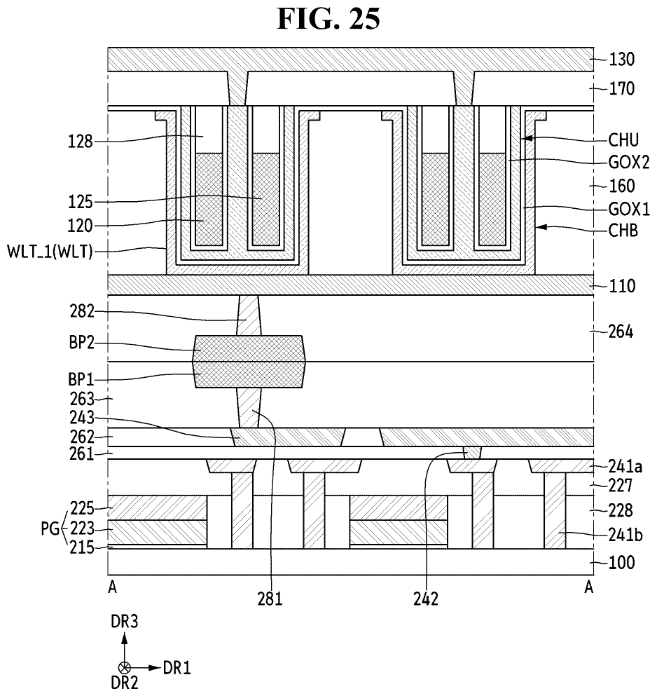

FIG. 25 is a diagram illustrating a semiconductor memory device according to some embodiments. For convenience, the following description focuses on the differences from the embodiment described with reference to FIG. 24.

Referring to FIG. 25, the semiconductor memory device according to some embodiments may further include a first bonding pad BP1 and a second bonding pad BP2.

The first bonding pad BP1 and a first pad plug 281 may be disposed on a second peripheral wiring line 243. The first bonding pad BP1 and the first pad plug 281 may be disposed within a third upper peripheral insulating film 263.

The first pad plug 281 may be disposed between the first bonding pad BP1 and the second peripheral wiring line 243. The first pad plug 281 may connect the first bonding pad BP1 and the second peripheral wiring line 243.

The second bonding pad BP2 and a second pad plug 282 may be disposed on the first bonding pad BP1. The second bonding pad BP2 and the second pad plug 282 may be disposed within a fourth upper peripheral insulating film 264.

The second bonding pad BP2 may be connected to the first bonding pad BP1. For example, the second bonding pad BP2 may be in contact with the first bonding pad BP1. Since the second bonding pad BP2 is electrically connected to the first bonding pad BP1, the second bonding pad BP2 may be connected to a first peripheral wiring line 241a and the second peripheral wiring line 243.

A conductive line 110 may be disposed on the second bonding pad BP2. The second pad plug 282 may be disposed between the conductive line 110 and the second bonding pad BP2. The second pad plug 282 may connect the conductive line 110 and the second bonding pad BP2.

Since the second bonding pad BP2 is connected to the first bonding pad BP1, the first and second peripheral wiring lines 241a and 243 may be connected to the conductive line 110. Although not illustrated, a first bitline 130, a second bitline (“140” in FIG. 5), first wordlines 120, and second wordlines 125 may be connected to the second bonding pad BP2.

The first and second pad plugs 281 and 282 may each include a conductive material containing metal. The first and second bonding pads BP1 and BP2 may each include a conductive material containing metal. The first and second bonding pads BP1 and BP2 are illustrated as single films, but are not limited thereto.

The fourth upper peripheral insulating film 264 may include an insulating material. The boundary between the third and fourth upper peripheral insulating films 263 and 264 is illustrated as being distinguishable, but is not limited thereto. If the third and fourth upper peripheral insulating films 263 and 264 include the same material, their boundary may not be distinguishable, and may be distinguished based on the boundary between the first and second bonding pads BP1 and BP2.

Although not illustrated, a bonding insulating film may be disposed between the third and fourth upper peripheral insulating films 263 and 264. For example, the bonding insulating film may include SiCN, but is not limited thereto.

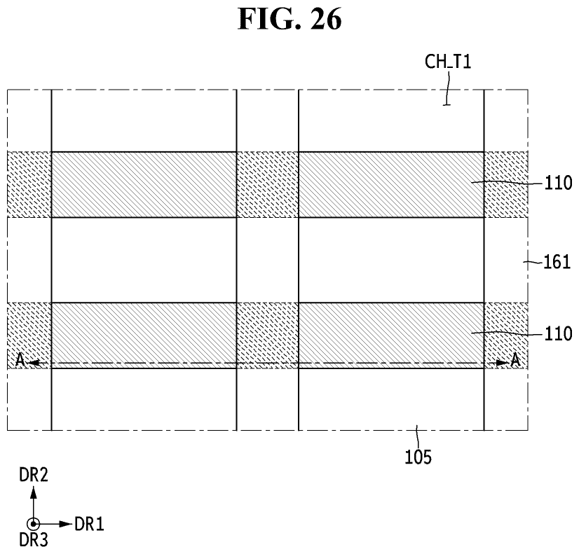

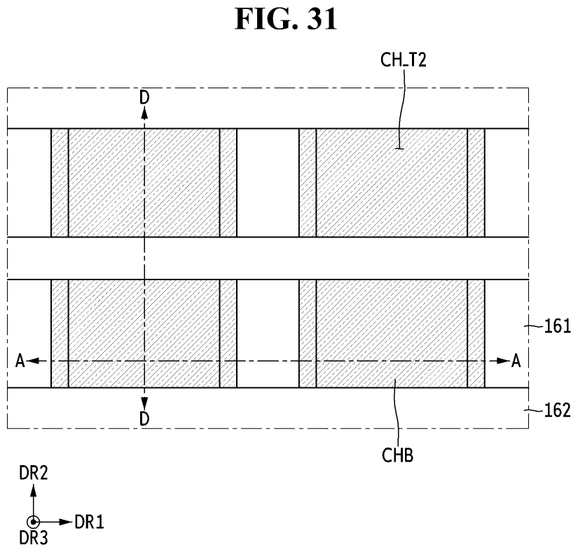

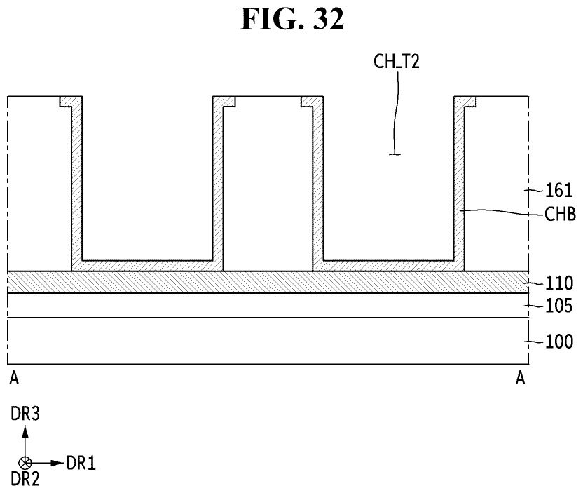

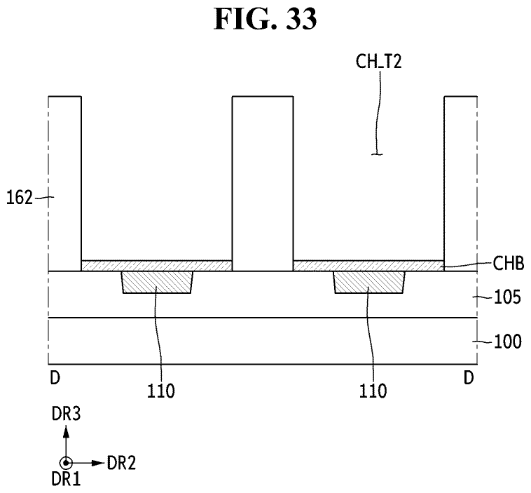

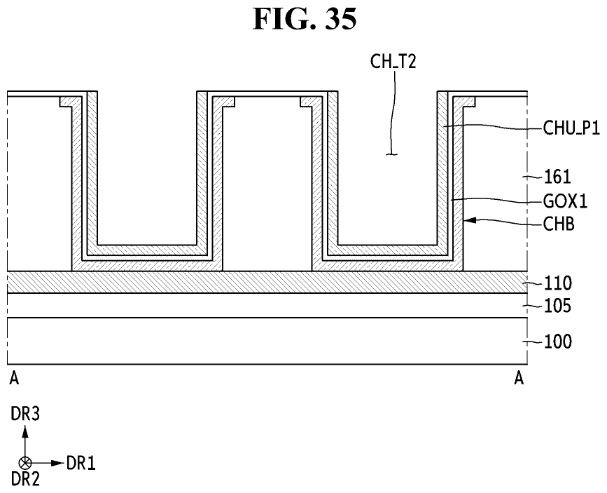

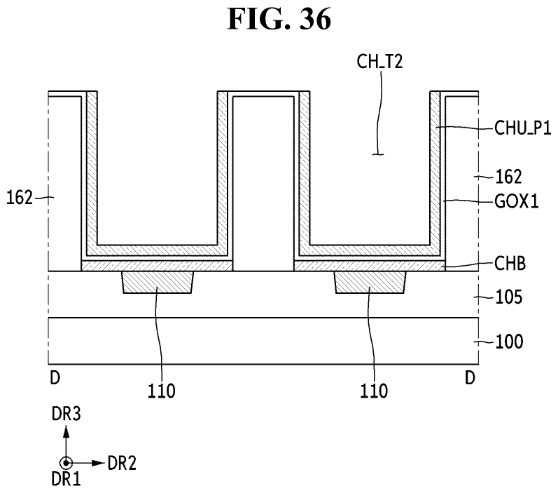

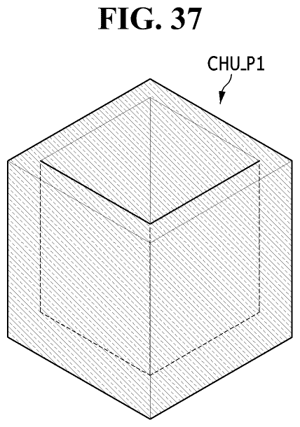

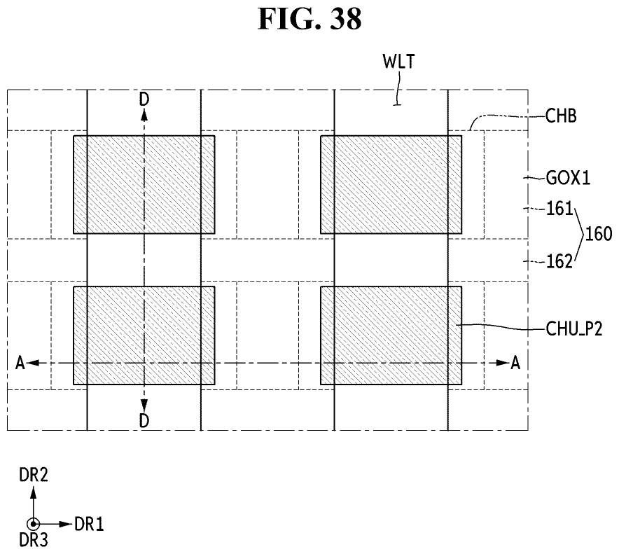

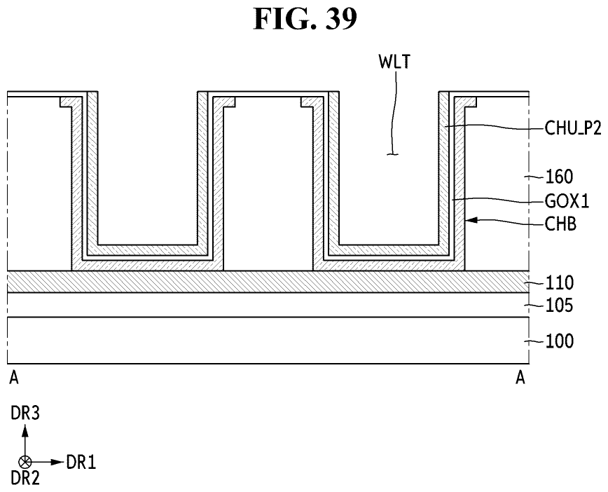

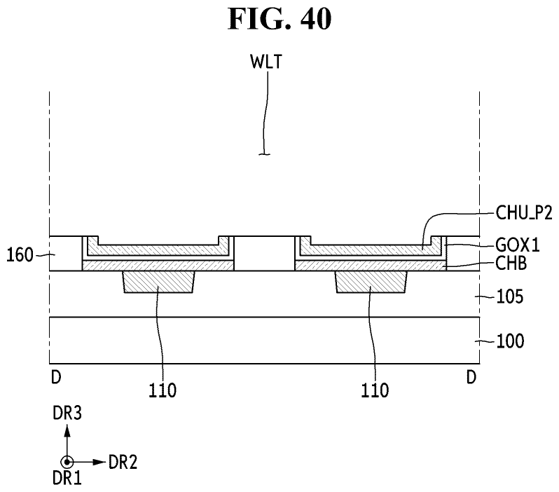

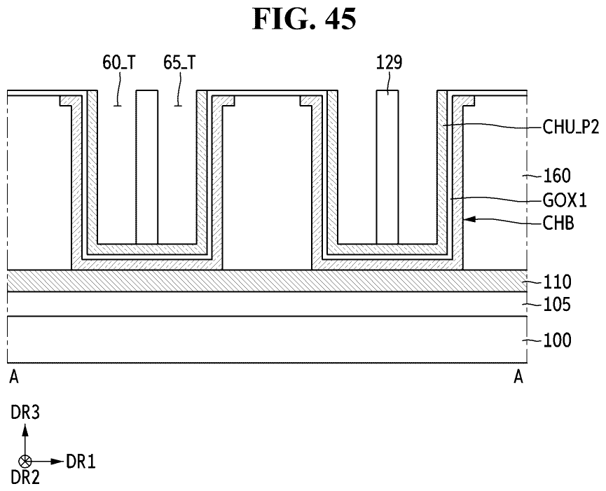

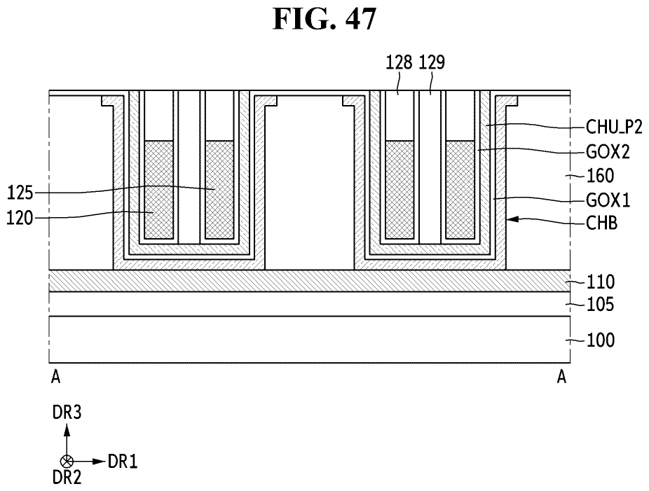

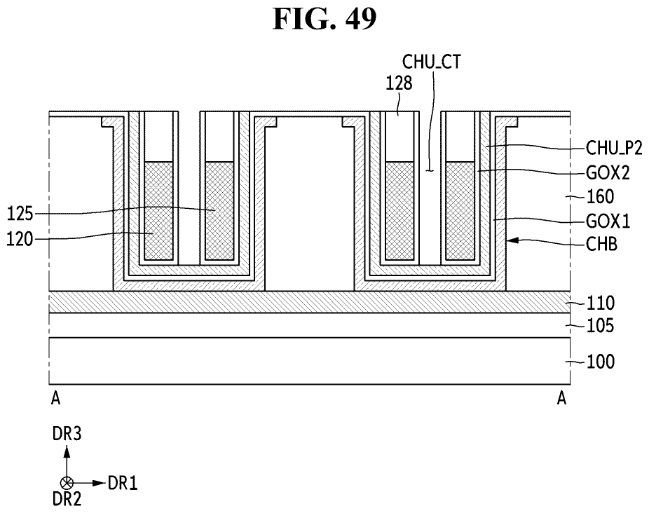

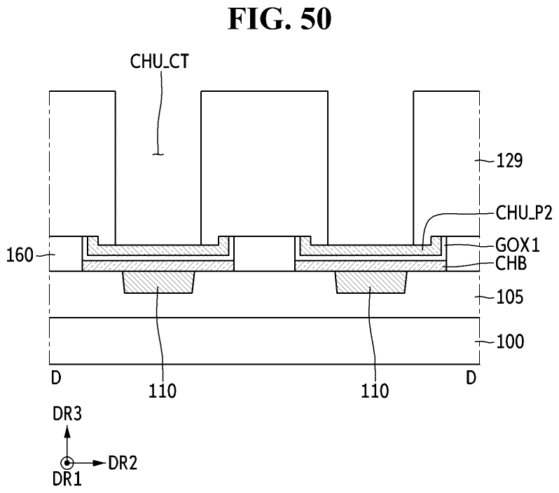

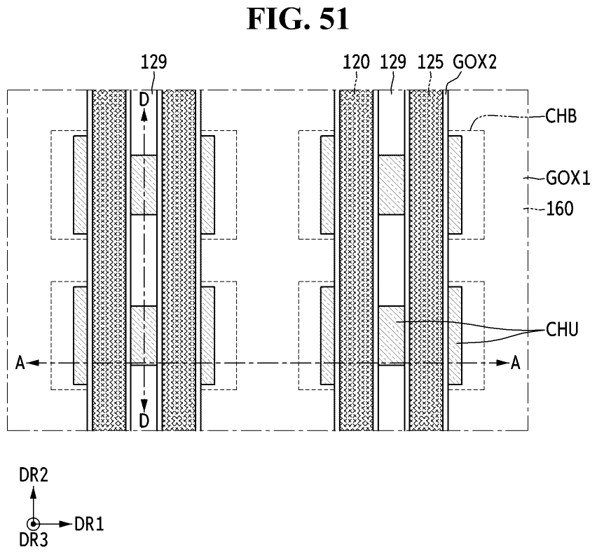

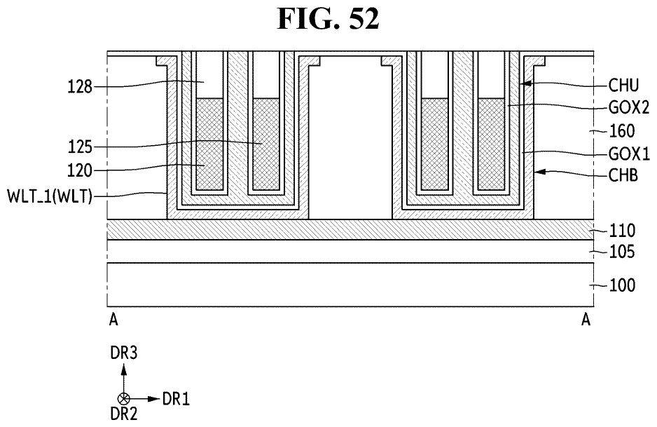

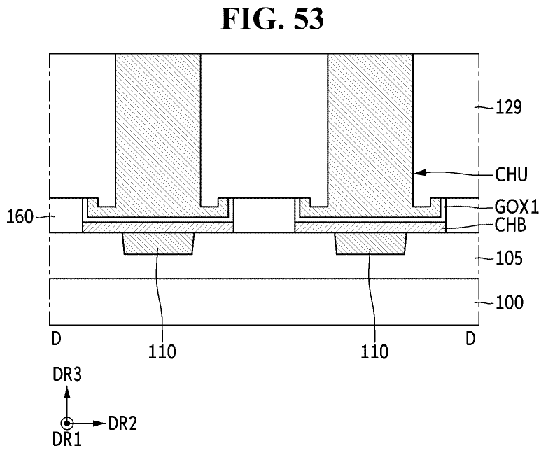

FIGS. 26 through 53 are diagrams illustrating a method of fabricating a semiconductor memory device according to some embodiments.

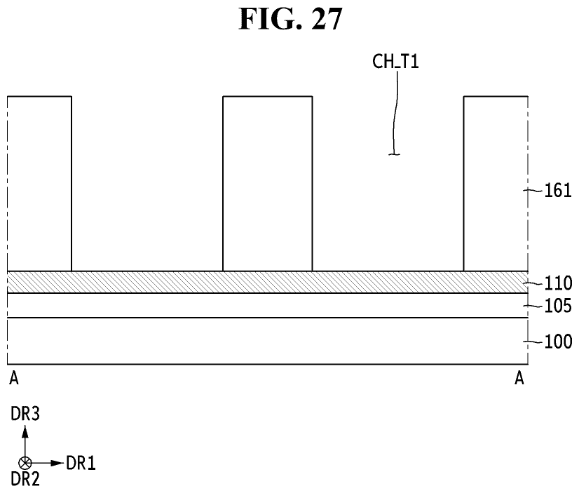

Referring to FIGS. 26 and 27, conductive lines 110 may be formed on a substrate 100.

The conductive lines 110 may each extend in the first direction DR1.

In one example, a lower insulating film 105 may be formed on the substrate 100. Conductive line trenches may be formed within the lower insulating film 105. Thereafter, conductive lines 110 filling the conductive line trenches may be formed within the lower insulating film 105.

In another example, a portion of the lower insulating film 105 may be formed on the substrate 100. A lower conductive film may be formed on the portion of the lower insulating film 105. Thereafter, a subtractive etching process may be performed to pattern the lower conductive film. Through this, the conductive lines 110 may be formed on the substrate 100. Thereafter, the remaining portion of the lower insulating film 105 exposing the conductive lines 110 may be formed on the conductive lines 110.

Thereafter, a first pre-mold pattern 161 may be formed on the lower insulating film 105 and the conductive lines 110. The first pre-mold pattern 161 may include a plurality of first channel trenches CH_T1. The first channel trenches CH_T1 may each extend in the second direction DR2. The first channel trenches CH_T1 may intersect the conductive lines 110.

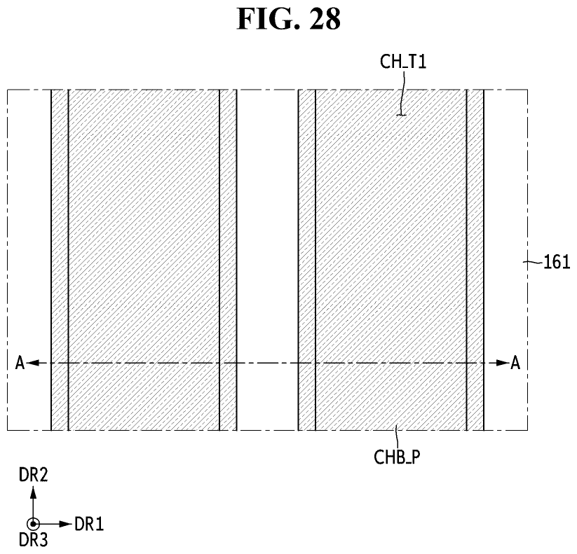

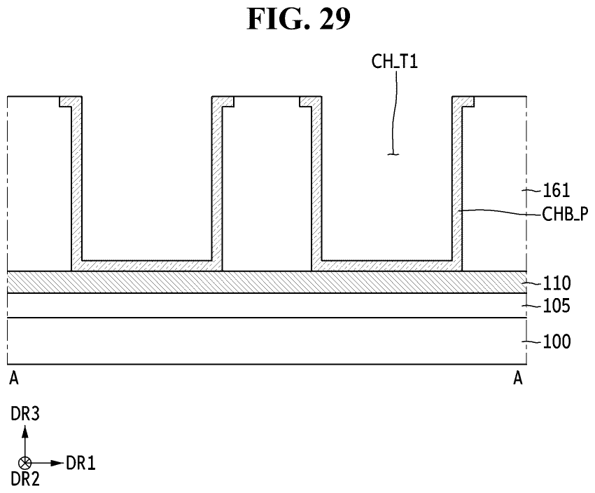

Referring to FIGS. 28 and 29, pre-lower channel patterns CHB_P may be formed on the lower insulating film 105 and the conductive lines 110.

The pre-lower channel patterns CHB_P may be formed along the sidewalls and bottom surfaces of the first channel trenches CH_T1. The pre-lower channel patterns CHB_P may extend in the second direction DR2.

Specifically, a pre-lower channel film may be formed along the sidewalls and bottom surfaces of the first channel trenches CH_T1. The pre-lower channel film may be formed along the upper surface of the first pre-mold pattern 161. Thereafter, pre-lower channel patterns CHB_P extending in the second direction DR2 may be formed by patterning the pre-lower channel film. The pre-lower channel patterns CHB_P may be formed by removing a portion of the pre-lower channel film formed on the upper surface of the first pre-mold pattern 161. Thereafter, an additional first pre-mold pattern 161 may be formed in the space where a portion of the pre-lower channel film has been removed, so that the uppermost surfaces of the pre-lower channel patterns CHB_P may be coplanar with the upper surface of the first pre-mold pattern 161.

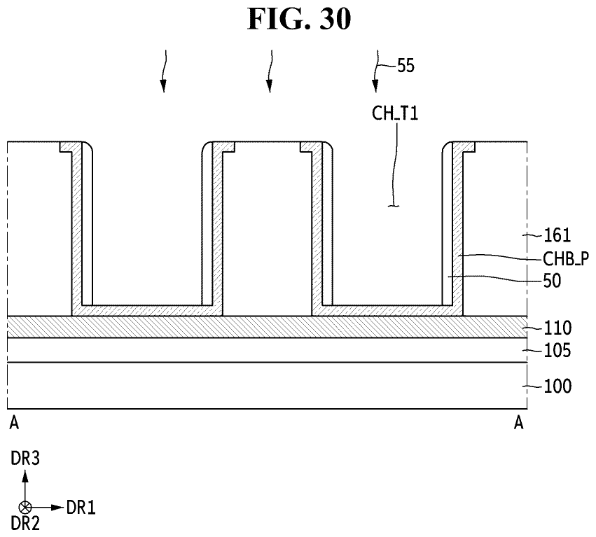

Referring to FIG. 30, impurity blocking spacers 50 may be formed on the pre-lower channel patterns CHB_P.

The impurity blocking spacers 50 may be formed along the sidewalls of the first channel trenches CH_T1. The impurity blocking spacers 50 may extend in the second direction DR2.

Thereafter, impurities may be injected into the exposed pre-lower channel patterns CHB_P, using an impurity doping process 55. For example, impurities may be injected into horizontal portions CHB_H of lower connection channel patterns CHB and extension portions CHB_VP2 of vertical portions CHB_V of the lower connection channel patterns CHB. The impurities introduced by the impurity doping process 55 may be of p-type or n-type. The type of the injected impurities may vary depending on the semiconductor material included in the pre-lower channel patterns CHB_P.

Depending on the semiconductor material included in the pre-lower channel patterns CHB_P, the impurity doping process 55 for injecting impurities into the lower channel patterns CHB_P may be omitted.

Referring to FIGS. 28 through 33, after the impurity doping process 55, the impurity blocking spacers 50 may be removed.

Thereafter, the lower connection channel patterns CHB may be formed by patterning the pre-lower channel patterns CHB_P. Specifically, first sacrificial material patterns may be formed within the first channel trenches CH_T1. Channel isolation trenches may be formed to cut through each of the pre-lower channel patterns CHB_P, thereby dividing it into multiple lower connection channel patterns CHB aligned in the second direction DR2. The channel isolation trenches may be formed within the first pre-mold pattern 161 and the first sacrificial material patterns. The channel isolation trenches may extend in the first direction DR1. After the lower connection channel patterns CHB are formed, channel cut patterns 162 filling the channel isolation trenches may be formed. Channel cut patterns 162 separating the pre-lower channel patterns CHB_P may be formed. Through this, a second pre-mold pattern (161 and 162), including the first pre-mold pattern 161 and the channel cut patterns 162, may be formed on the conductive lines 110 and the lower insulating film 105.

Thereafter, second channel trenches CH_T2 may be formed by removing the first sacrificial material patterns. The second channel trenches CH_T2 may be defined by the first pre-mold pattern 161 and the channel cut patterns 162. For example, the second channel trenches CH_T2 may be defined by the second pre-mold pattern (161 and 162). The lower connection channel patterns CHB may be formed within the second channel trenches CH_T2, respectively.

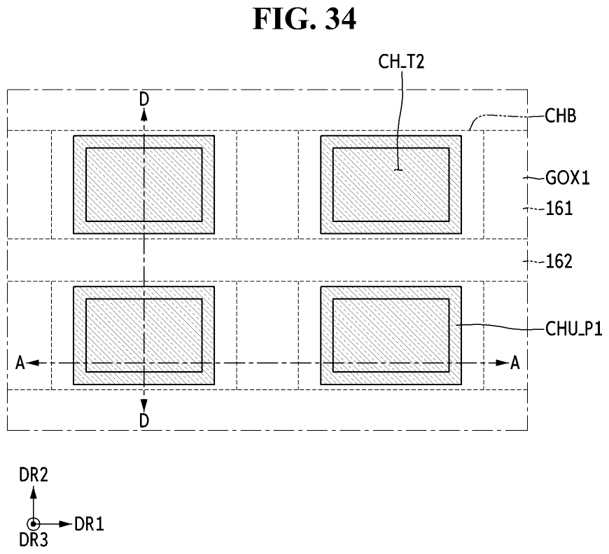

Referring to FIGS. 34 through 37, first gate insulating patterns GOX1 may be formed on the lower connection channel patterns CHB.

The first gate insulating patterns GOX1 may be formed along the sidewalls and bottom surfaces of second channel trenches CH_T2. The first gate insulating patterns GOX1 may be formed along the upper surface of the second pre-mold pattern (161 and 162).

Thereafter, first pre-upper panel patterns CHU_P1 may be formed on the first gate insulating patterns GOX1. The first pre-upper panel patterns CHU_P1 may be formed within the second channel trenches CH_T2. The first pre-upper panel patterns CHU_P1 may be formed along the sidewalls and bottom surfaces of the second channel trenches CH_T2.

The first pre-upper panel patterns CHU_P1 may have, for example, an open-box shape, but are not limited thereto.

Contrary to what is illustrated, insertion channel metal patterns (“151” in FIG. 11) or insertion ferroelectric material patterns (“153” in FIG. 12) may be formed before the formation of the first pre-upper panel patterns CHU_P1.

Referring to FIGS. 34 through 40, wordline trenches WLT may be formed by partially removing the second pre-mold pattern (161 and 162) and the first pre-upper panel patterns CHU_P1.

The wordline trenches WLT may extend in the second direction DR2. A mold insulating pattern 160, including the wordline trenches WLT, may be formed. During the formation of the wordline trenches WLT, second pre-upper panel patterns CHU_P2 may be formed.

Specifically, second sacrificial material patterns may be formed within the second channel trenches CH_T2. Thereafter, the wordline trenches WLT may be formed within the second sacrificial material patterns, the second pre-mold pattern (161 and 162), and the first pre-upper panel patterns CHU_P1. Thereafter, the second sacrificial material patterns may be removed.

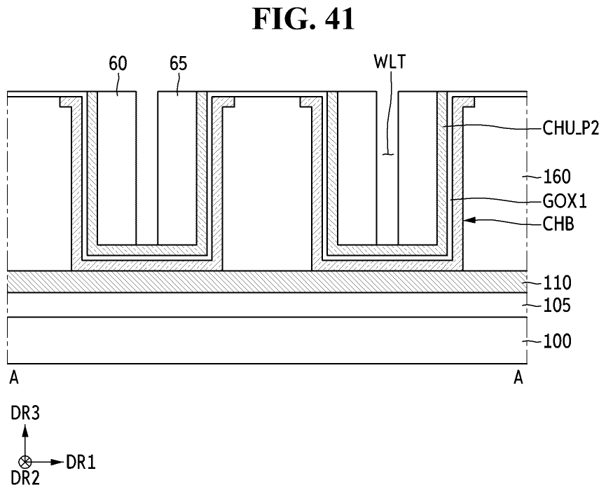

Referring to FIG. 41, first wordline mold spacers 60 and second wordline mold spacers 65 may be formed within the wordline trenches WLT.

The first wordline mold spacers 60 and the second wordline mold spacers 65 may be formed on the second pre-upper panel patterns CHU_P2. The first wordline mold spacers 60 and the second wordline mold spacers 65 may each extend in the second direction DR2. Within the wordline trenches WLT, the first wordline mold spacers 60 and the second wordline mold spacers 65 may be spaced apart in the first direction DR1.

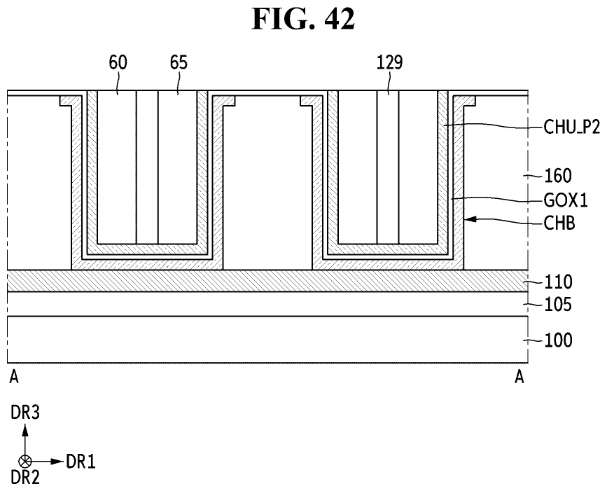

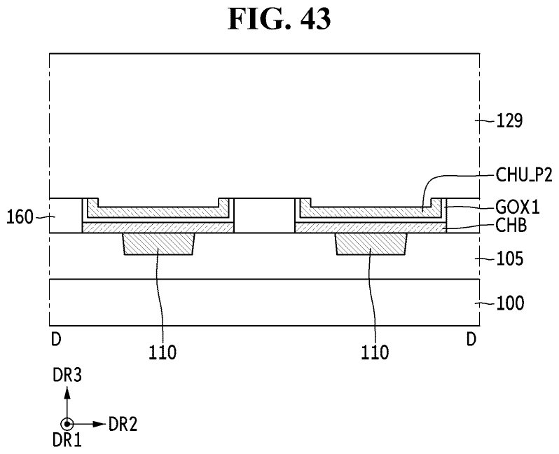

Referring to FIGS. 42 and 43, wordline separation patterns 129 may be formed between the first wordline mold spacers 60 and the second wordline mold spacers 65.

The wordline isolation patterns 129 may be formed within the wordline trenches WLT. The wordline isolation patterns 129 may extend in the second direction DR2.

Referring to FIGS. 42 through 45, after removing the first wordline mold spacers 60 and the second wordline mold spacers 65, first mold spacer trenches 60_T and second mold spacer trenches 65_T may be formed.

The first mold spacer trenches 60_T and the second mold spacer trenches 65_T may expose the second pre-upper panel patterns CHU_P2. The first mold spacer trenches 60_T and the second mold spacer trenches 65_T may be disposed on both sides of the wordline isolation patterns 129. The first mold spacer trenches 60_T and the second mold spacer trenches 65_T may each extend in the second direction DR2.

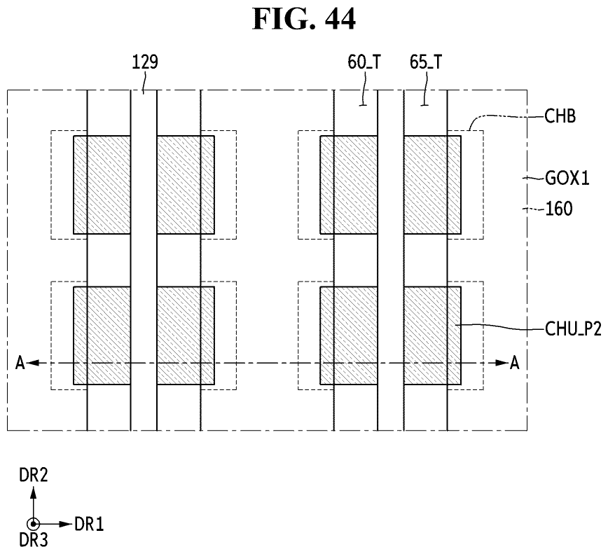

Referring to FIGS. 44 through 47, second gate insulating patterns GOX2 may be formed on the second pre-upper panel patterns CHU_P2.

The second gate insulating patterns GOX2 may be formed along the sidewalls and bottom surfaces of the first mold spacer trenches 60_T and the sidewalls and bottom surfaces of the second mold spacer trenches 65_T.

Thereafter, first wordlines 120 and second wordlines 125 may be formed on the second gate insulating patterns GOX2. The first wordlines 120 may be formed within the first mold spacer trenches 60_T. The first wordlines 120 may fill portions of the first mold spacer trenches 60_T. The second wordlines 125 may be formed within the second mold spacer trenches 65_T. The second wordlines 125 may fill portions of the second mold spacer trenches 65_T.

Wordline capping patterns 128 may be formed on the first wordlines 120 and the second wordlines 125. The wordline capping pattern 128 may fill the remaining portions of the first mold spacer trenches 60_T and the remaining portions of the second mold spacer trenches 65_T.

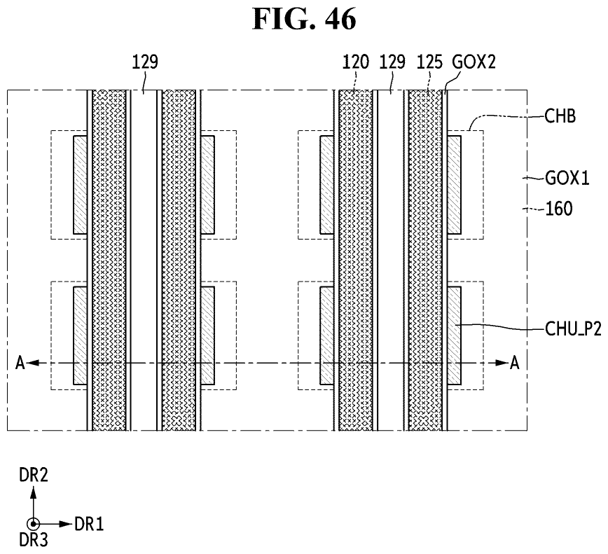

Referring to FIGS. 46 through 50, upper channel holes CHU_CT may be formed between the first wordlines 120 and the second wordlines 125 by removing portions of the wordline isolation patterns 129.

The upper channel holes CHU_CT may expose portions of the second pre-upper panel patterns CHU_P2.

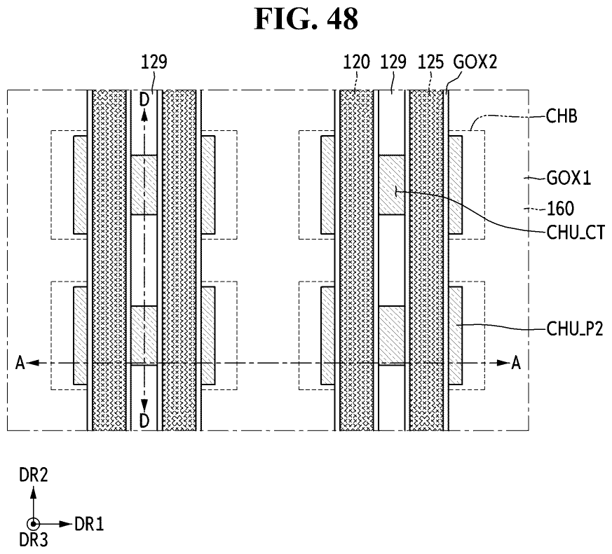

Referring to FIGS. 48 through 53, third pre-upper channel patterns filling the upper channel holes CHU_CT may be formed.

The third pre-upper channel patterns may be in contact with the second pre-upper panel patterns CHU_P2. The third pre-upper channel patterns may correspond to the third vertical portions CHU_V3 of the upper connection channel patterns CHU in FIG. 9. Through this, upper connection channel patterns CHU may be formed on the lower connection channel patterns CHB.

Contrary to what is illustrated, connection channel conductive patterns (“155” in FIG. 13) may be formed within the upper channel holes CHU_CT. In this case, the second pre-upper panel patterns CHU_P2 may correspond to the upper connection channel patterns CHU.

Thereafter, referring to FIGS. 4 through 8, first bitlines 130 and second bitlines 140 may be formed on the upper connection channel patterns CHU and the lower connection channel patterns CHB.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor memory device comprising:
a first conductive line on a substrate;
a first bitline spaced apart from the first conductive line in a first direction and extending in a second direction intersecting the first direction;
a second bitline spaced apart from the first conductive line in the first direction, extending in the second direction, and spaced apart from the first bitline in a third direction intersecting the first direction and the second direction;
a first wordline disposed between the first conductive line and each of the first bitline and the second bitline and extending in the third direction;
a first channel pattern including:
a horizontal portion extending in the second direction and disposed between the first wordline and the first conductive line, and
a first vertical portion extending in the first direction,
wherein the horizontal portion of the first channel pattern is connected to the first conductive line, and
wherein the first vertical portion of the first channel pattern is connected to the first bitline; and
a second channel pattern disposed between the first channel pattern and the first wordline and connected to the second bitline.

2. The semiconductor memory device of claim 1,
wherein the second channel pattern includes:
a first vertical portion disposed between the first vertical portion of the first channel pattern and the first wordline; and
a horizontal portion disposed between the horizontal portion of the first channel pattern and the first wordline, and
wherein the first vertical portion of the second channel pattern is directly connected to the horizontal portion of the second channel pattern.

3. The semiconductor memory device of claim 2,
wherein the second channel pattern further includes a second vertical portion spaced apart from the first vertical portion of the second channel pattern in the second direction,
wherein the first wordline is disposed between the first vertical portion of the second channel pattern and the second vertical portion of the second channel pattern, and
wherein the second bitline is connected to the second vertical portion of the second channel pattern.

4. The semiconductor memory device of claim 2, further comprising:
a connection channel conductive pattern spaced apart from the first vertical portion of the second channel pattern in the second direction and extending along a sidewall of the first wordline,
wherein the first wordline is disposed between the first vertical portion of the second channel pattern and the connection channel conductive pattern,
wherein the connection channel conductive pattern includes a lower end connected to the horizontal portion of the second channel pattern and an upper end connected to the second bitline, and
wherein the first vertical portion of the second channel pattern, the first vertical portion of the first channel pattern, the first wordline, and the connection channel conductive pattern, the first bitline connected to the first vertical portion of the first channel pattern, and the second bitline connected to the connection channel conductive pattern constitute a first memory cell.

5. The semiconductor memory device of claim 1, further comprising:
a second wordline extending in the third direction and spaced apart from the first wordline in the second direction,
wherein the first channel pattern further includes:
a second vertical portion spaced apart from the first vertical portion of the first channel pattern in the second direction and directly connected to the horizontal portion of the first channel pattern, and
wherein the first wordline and the second wordline are disposed between the first vertical portion of the first channel pattern and the second vertical portion of the first channel pattern.

6. The semiconductor memory device of claim 5,
wherein the second channel pattern includes:
a first vertical portion disposed between the first vertical portion of the first channel pattern and the first wordline;
a second vertical portion disposed between the second vertical portion of the first channel pattern and the second wordline; and
a horizontal portion connecting the first vertical portion of the second channel pattern to the second vertical portion of the second channel pattern.

7. The semiconductor memory device of claim 6,
wherein the second channel pattern further includes a third vertical portion extending in the first direction and disposed between the first wordline and the second wordline,
wherein the third vertical portion of the second channel pattern includes a lower end connected to the horizontal portion of the second channel pattern and an upper end connected to the second bitline, and
wherein the second vertical portion of the second channel pattern, the second vertical portion of the first channel pattern, the second wordline, and the third vertical portion of the second channel pattern, the first bitline connected to the second vertical portion of the first channel pattern, and the second bitline connected to the third vertical portion of the second channel pattern constitute a second memory cell.

8. The semiconductor memory device of claim 5,
wherein the second vertical portion of the first channel pattern is connected to the first bitline.

9. The semiconductor memory device of claim 5, further comprising:
a third bitline spaced apart from the first conductive line in the first direction and extending in the second direction,
wherein the second bitline is disposed between the first bitline and the third bitline, and
wherein the third bitline is connected to the second vertical portion of the first channel pattern.

10. The semiconductor memory device of claim 1, further comprising:
an insertion channel metal pattern disposed between the first vertical portion of the first channel pattern and the first wordline and contacting the second channel pattern.

11. The semiconductor memory device of claim 1, further comprising:
an insertion ferroelectric material pattern disposed between the first vertical portion of the first channel pattern and the first wordline and contacting the second channel pattern.

12. The semiconductor memory device of claim 1, further comprising:
a second conductive line spaced apart from the first conductive line in the third direction and extending in the second direction; and
a third channel pattern spaced apart from the first channel pattern in the third direction and connected to the second conductive line,
wherein the first conductive line extends in the second direction,
wherein the first channel pattern is not directly connected to the second conductive line, and
wherein the third channel pattern is not directly connected to the first conductive line.

13. The semiconductor memory device of claim 1, further comprising:
a third channel pattern spaced apart from the first channel pattern in the third direction and connected to the first conductive line.

14. A semiconductor memory device comprising:
a conductive line on a substrate;
a first bitline spaced apart from the conductive line in a first direction and extending in a second direction intersecting the first direction;
a second bitline spaced apart from the conductive line in the first direction, extending in the second direction, and spaced apart from the first bitline in a third direction intersecting the first direction and the second direction;
a first wordline disposed between the conductive line and each of the first bitline and the second bitline and extending in the third direction;
a first channel pattern disposed between the first wordline and the conductive line and connected to the first bitline and the conductive line; and
a second channel pattern disposed between the first channel pattern and the first wordline and connected to the second bitline,
wherein the first wordline includes a first sidewall and a second sidewall that are opposite to each other in the second direction, and
wherein the second channel pattern includes:
a first vertical portion extending along the first sidewall of the first wordline,
a second vertical portion extending along the second sidewall of the first wordline, and
a horizontal portion connecting the first vertical portion of the second channel pattern and the second vertical portion of the second channel pattern.

15. The semiconductor memory device of claim 14, further comprising:
a second wordline extending in the third direction and spaced apart from the first wordline in the second direction,
wherein the second wordline includes a first sidewall and a second sidewall that are opposite to each other in the second direction,
wherein the second sidewall of the second wordline is adjacent to the second sidewall of the first wordline,
wherein the second channel pattern further includes:
a third vertical portion that is spaced apart from the second vertical portion of the second channel pattern in the second direction and connected to the horizontal portion of the second channel pattern,
wherein the second vertical portion of the second channel pattern is disposed between the second sidewall of the first wordline and the second sidewall of the second wordline, and
wherein the third vertical portion of the second channel pattern extends along the first sidewall of the second wordline.

16. The semiconductor memory device of claim 14,
wherein the first channel pattern further includes:
a horizontal portion extending in the second direction between the second channel pattern and the conductive line; and
a first vertical portion extending in the first direction along the first vertical portion of the second channel pattern,
wherein the horizontal portion of the first channel pattern is connected to the conductive line, and
wherein the first vertical portion of the first channel pattern is connected to the first bitline.

17. The semiconductor memory device of claim 16,
wherein the first channel pattern further includes:
a second vertical portion that is spaced apart from the first vertical portion of the first channel pattern in the second direction and directly connected to the horizontal portion of the first channel pattern, and
wherein the first wordline is disposed between the first vertical portion of the first channel pattern and the second vertical portion of the first channel pattern.

18. A semiconductor memory device comprising:
a conductive line disposed on a substrate and extending in a first direction;
a first bitline spaced apart from the conductive line in a second direction intersecting the first direction and extending in the first direction;
a second bitline spaced apart from the conductive line in the second direction, extending in the first direction, and spaced apart from the first bitline in a third direction intersecting the first direction and the second direction;
a first channel pattern including:
a horizontal portion extending in the first direction,
a first vertical portion extending in the second direction, and
a second vertical portion extending in the second direction,
wherein the first vertical portion of the first channel pattern and the second vertical portion of the first channel pattern are directly connected to opposite ends of the horizontal portion of the first channel pattern, respectively,
wherein the horizontal portion of the first channel pattern is connected to the conductive line, and
wherein the first vertical portion of the first channel pattern and the second vertical portion of the first channel pattern are connected to the first bitline;
a first wordline disposed between the first vertical portion of the first channel pattern and the second vertical portion of the first channel pattern;
a second wordline disposed between the first wordline and the second vertical portion of the first channel pattern; and
a second channel pattern disposed between the first channel pattern and each of the first wordline and the second wordline and connected to the second bitline.

19. The semiconductor memory device of claim 18,
wherein the second channel pattern includes:
a first vertical portion disposed between the first vertical portion of the first channel pattern and the first wordline;
a second vertical portion disposed between the second vertical portion of the first channel pattern and the second wordline;
a third vertical portion disposed between the first wordline and the second wordline; and
a horizontal portion disposed between the horizontal portion of the first channel pattern and each of the first wordline and the second wordline.

20. The semiconductor memory device of claim 18, further comprising:
a connection channel conductive pattern disposed between the first wordline and the second wordline,
wherein a material of the connection channel conductive pattern is different from a material of the second channel pattern,
wherein the second channel pattern includes:
a first vertical portion disposed between the first vertical portion of the first channel pattern and the first wordline;
a second vertical portion disposed between the second vertical portion of the first channel pattern and the second wordline; and
a horizontal portion including opposite ends connected to the first vertical portion of the second channel pattern and the second vertical portion of the second channel pattern, respectively, and
wherein the connection channel conductive pattern is connected to the horizontal portion of the second channel pattern.
